(19) United States
(12) Patent Application Publication
(10) Pub. No.: US 2025/0126915 A1
(43) Pub. Date: Apr. 17, 2025

(54) SEMICONDUCTOR STRUCTURES AND METHODS OF FORMING THE SAME

(71) Applicant: Taiwan Semiconductor Manufacturing Company, Ltd., Hsinchu (TW)

(72) Inventors: Chih-Kuan YU, Nantou County (TW); Wen-I HSU, Tainan City (TW); Feng-Chi HUNG, Tainan City (TW); Hsin-Hung CHEN, Tainan City (TW); Jen-Cheng LIU, Hsin-Chu City (TW); Dun-Nian YAUNG, Taipei City (TW)

(21) Appl. No.: 18/486,382

(22) Filed: Oct. 13, 2023

(51) Int. Cl. H01L 27/146

(52) U.S. Cl. CPC H10F 39/807; H10F 39/014; H10F 39/018; H10F 39/809

(57) ABSTRACT

A p-type doping region around an isolation structure provides additional electrical isolation between pixel sensors of a pixel array. As a result, current leakage from a floating node of one pixel sensor into another is reduced. Therefore, dark current is reduced, and performance of the pixel array is improved. Additionally, pixel noise caused by electrons trapped in the isolation structure may be reduced.

### BACKGROUND

A complementary metal oxide semiconductor (CMOS) image sensor may include a plurality of pixel sensors. A pixel sensor of the CMOS image sensor may include a transfer gate, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B are diagrams of an example two-chip implementation described herein.

FIGS. 1C-1D are diagrams of an example three-chip implementation described herein.

FIGS. 2A-2C are diagrams of example dual-pixel implementations described herein.

FIGS. 2D-2E are diagrams of an example quad-pixel implementation described herein.

FIG. 3 is a diagram of an example isolation structure described herein.

FIGS. 4A-4K are diagrams of an example implementation described herein.

FIGS. 5A-5I are diagrams of an example implementation described herein.

FIGS. 6A-6I are diagrams of an example implementation described herein.

FIG. 7 is a flowchart of an example process associated with forming a semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Optical crosstalk can occur between adjacent pixel regions in a pixel array. Optical crosstalk is a pixel array performance issue, whereby incident light passes through a pixel sensor at a non-orthogonal angle and is at least partially absorbed by a photodiode of an adjacent pixel sensor. Optical crosstalk in a pixel array of an image sensor can degrade the spatial resolution of the image sensor, can reduce overall sensitivity of the image sensor, can cause color mixing between pixel sensors of the image sensor, and/or can lead to image noise after color correction.

In order to reduce optical crosstalk, an isolation structure, such as a deep trench isolation (DTI) structure may surround the pixel sensors. However, any damage caused during formation of the DTI structure allows for current leakage from a floating diffusion (FD) node of one pixel sensor into another. Some damage may be corrected with thermal annealing; however, remaining damage still allows for current leakage.

Some implementations described herein provide techniques and apparatuses for p-type doping around an isolation structure. The p-type doping provides additional electrical isolation between pixel sensors. As a result, current leakage from an FD node of one pixel sensor into another is reduced. Therefore, dark current is reduced, and performance of the pixel array is improved. Additionally, pixel noise caused by electrons trapped in the isolation structure may be reduced.

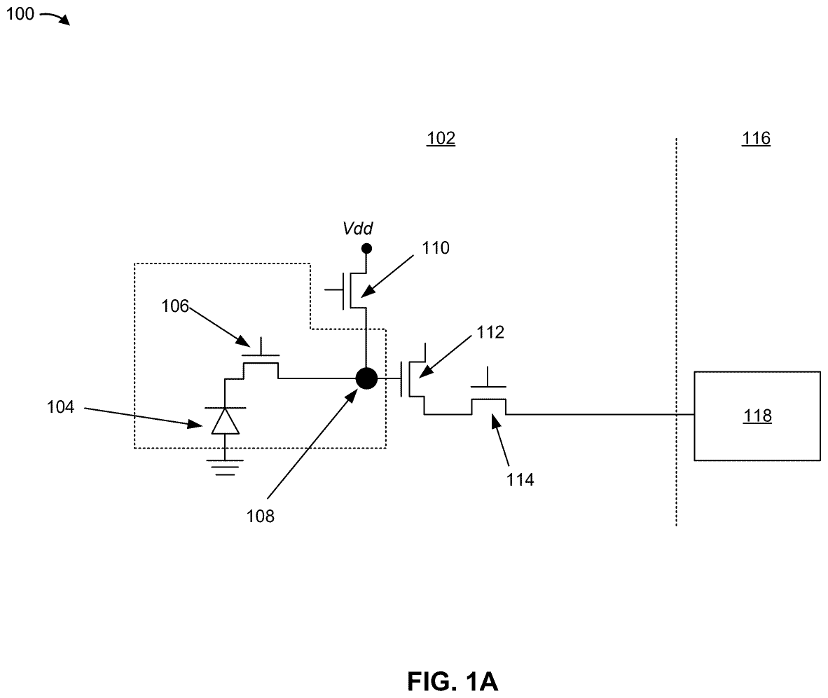

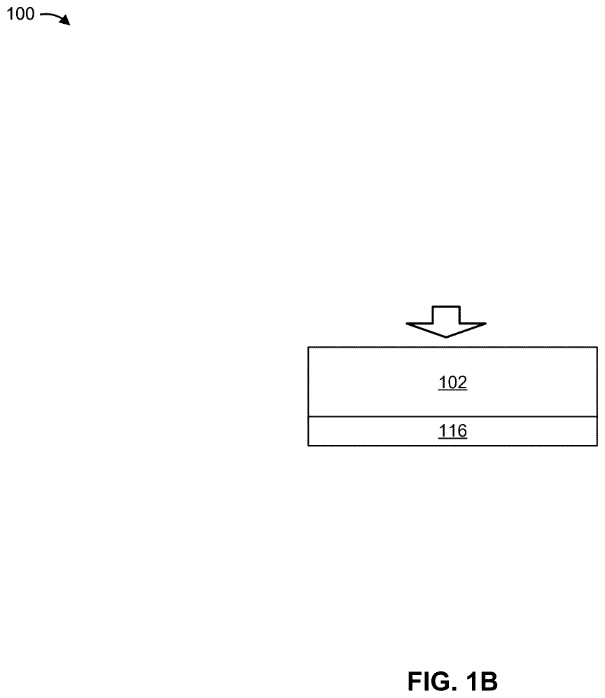

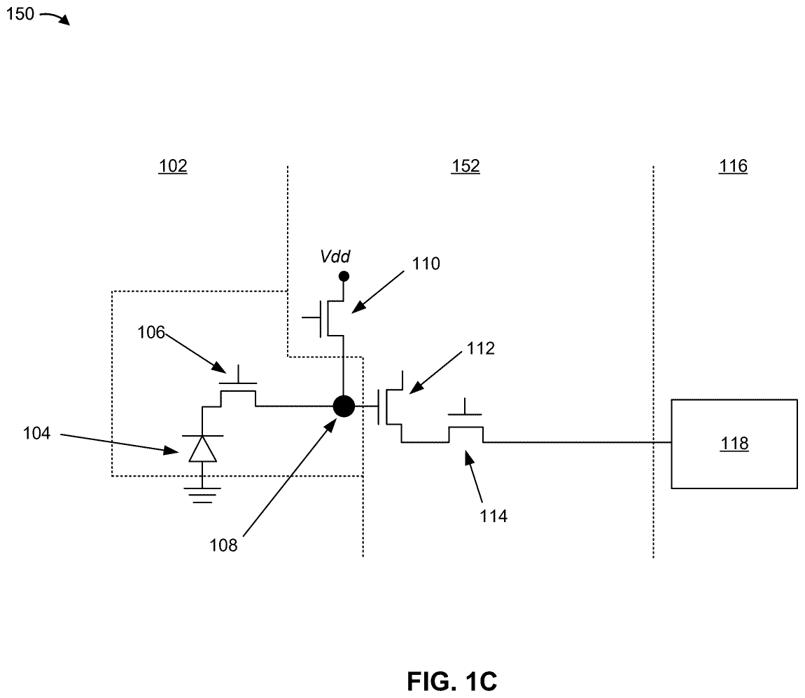

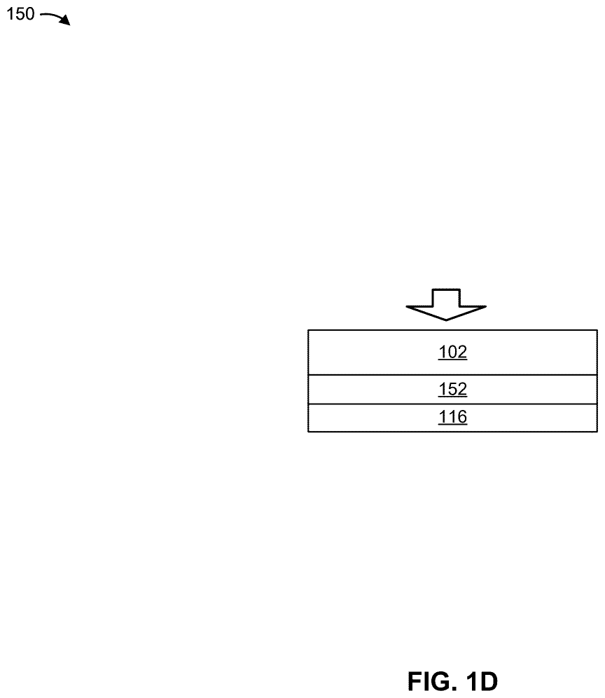

FIG. 1A is a diagram of example circuitry 100 described herein. The example circuitry 100 is shown for an image sensor formed across two chips. The image sensor may be a CMOS image sensor, a backside illuminated (BSI) CMOS image sensor, or another type of image sensor.

As shown in FIG. 1A, a first chip 102 includes front-end components of the image sensor. Signals from a photodiode 104 are controlled by a transfer transistor 106 and transferred to a floating node (also referred to as an FD node) 108. Additionally, a reset gate 110 uses a voltage represented by Vdd to reset the floating node 108 to zero charge. The first chip 102 additionally includes back-end routing (not shown in FIG. 1A). As shown in FIG. 1A, a second chip 116 includes an application-specific integrated circuit (ASIC) 118. The first chip 102 and the second chip 116 may be connected using back-end metal routing and M-M and D-D bonding. A source follower (SF) transistor 112 and row selector (RS) transistor 114 control output of signals from the floating node 108 to the ASIC 118.

FIG. 1B is a cross-section view of the example circuitry 100 of FIG. 1A. As shown in FIG. 1B, light is incident on the first chip 102 (e.g., on a backside of the first chip 102). The frontside of the chip is bonded to the second chip 116. As a result, the SF transistor 112 and RS transistor 114, formed in the first chip 102, may electrically connect to the ASIC 118 formed in the second chip 116.

As indicated above, FIGS. 1A-1B are provided as an example. Other examples may differ from what is described with regard to FIGS. 1A-1B. For example, in order to store additional charge from the photodiode 104 in brighter conditions, a dual conversion gain (DCG) capacitor may be included near the floating node 108.

FIG. 1C is a diagram of example circuitry 150 described herein. The example circuitry 150 is shown for an image sensor formed across three chips. The image sensor may be a CMOS image sensor, a BSI CMOS image sensor, or another type of image sensor.

The example circuitry 150 is similar to the example circuitry 100 except that the first chip 102 only includes the photodiode 104, the transfer transistor 106, and the floating node 108. Accordingly, the reset gate 110, the SF transistor 112, and the RS transistor 114 are included in a third chip 152. The third chip 152 is between the first chip 102 and the second chip 116 and thus connects the photodiode 104 to the ASIC 118.

FIG. 1D is a cross-section view of the example circuitry 150 of FIG. 1C. As shown in FIG. 1D, light is incident on the first chip 102 (e.g., on a backside of the first chip 102). The frontside of the first chip 102 is bonded to the third chip 152, which in turn is bonded to the second chip 116. As a result, the transfer transistor 106, formed in the first chip 102, may electrically connect to the floating node 108 and then connect through a back-end to the SF transistor 112 and RS transistor 114, formed in the third chip 152. Moreover, the SF transistor 112 and RS transistor 114 may electrically connect to the ASIC 118 formed in the second chip 116.

As indicated above, FIGS. 1C-1D are provided as an example. Other examples may differ from what is described with regard to FIGS. 1C-1D. For example, in order to store additional charge from the photodiode 104 in brighter conditions, a DCG capacitor may be included near the floating node 108 in the first chip 102 or the third chip 152.

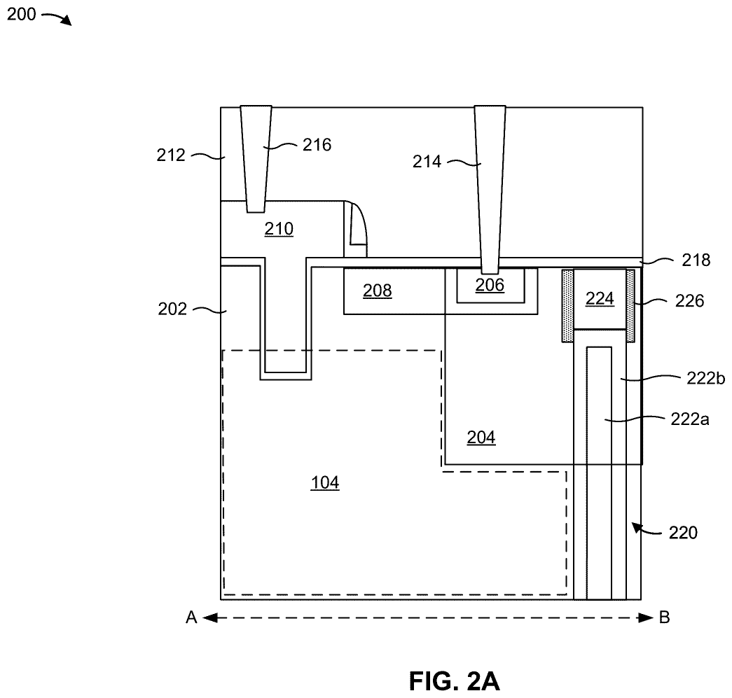

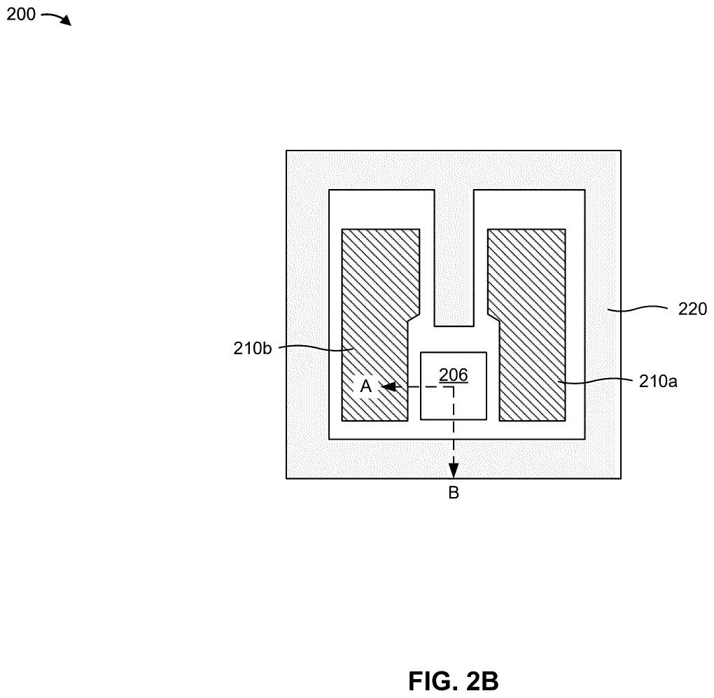

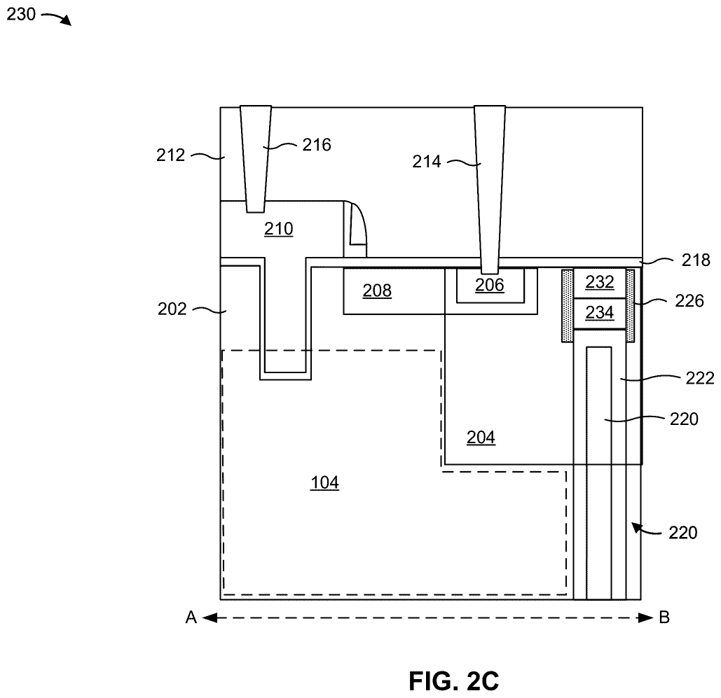

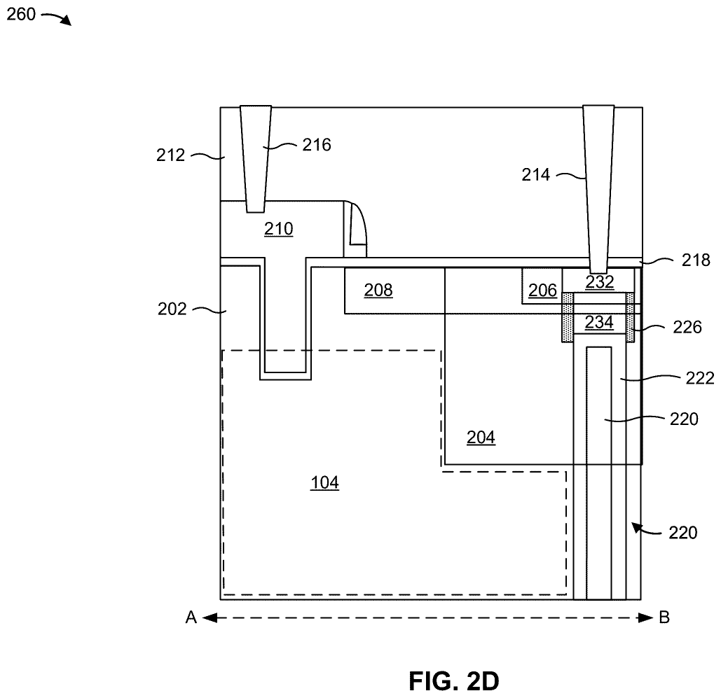

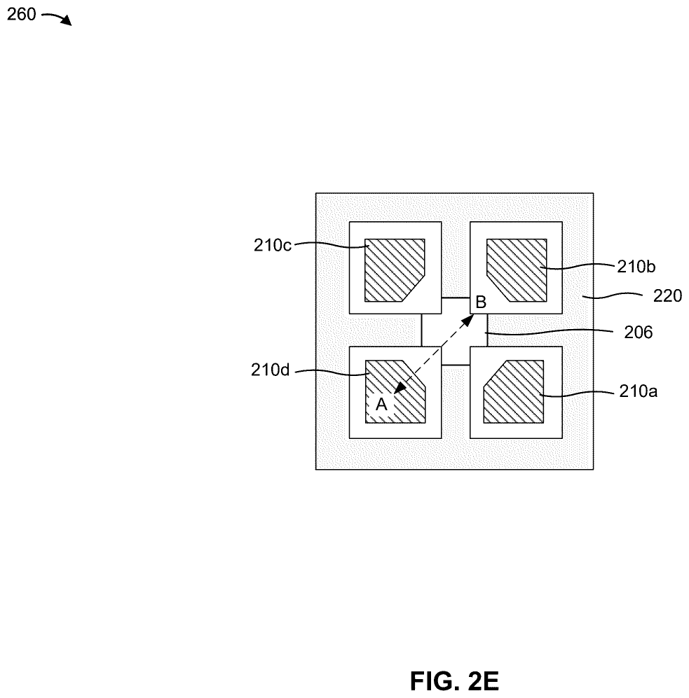

FIG. 2A illustrates a cross-section view of a pixel sensor 200. As shown in FIG. 2A, the pixel sensor 200 may include a substrate 202. The substrate 202 may include a semiconductor die substrate, a semiconductor wafer, or another type of substrate in which semiconductor pixels may be formed. In some implementations, the substrate 202 is formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 202 is formed of a doped material (e.g., a p-doped material or an n-doped material) such as a doped silicon.

The pixel sensor 200 may include a photodiode 104 included in the substrate 202. The photodiode 104 may include a plurality of regions that are doped with various types of ions to form a p-n junction or a PIN junction (e.g., a junction between a p-type portion, an intrinsic (or undoped) type portion, and an n-type portion). For example, the substrate 202 may be doped with an n-type dopant to form one or more n-type regions of the photodiode 104, and the substrate 202 may be doped with a p-type dopant to form a p-type region of the photodiode 104. The photodiode 104 may be configured to absorb photons of incident light. The absorption of photons causes the photodiode 104 to accumulate a charge (referred to as a photocurrent) due to the photoelectric effect. Photons may bombard the photodiode 104, which causes emission of electrons in the photodiode 104.

The pixel sensor 200 may further include a p-type well 204. In some implementations, the p-type well 204 may allow for formation of the n-type doping region (also referred to as an “n-type source/drain region”) 206 that comprises the floating node 108. Additionally, the pixel sensor 200 may include a drain extension region 208 coupled and/or electrically connected to the n-type doping region 206. The drain extension region 208 may include a lightly-doped n-type region that facilitates the transfer of photocurrent from the photodiode 104 to the n-type doping region 206. Conceptually, the n-type doping region 206 that comprises the floating node 108, and the drain extension region 208 is associated with (and activated by) a transfer gate 210 (e.g., comprising a portion of a transfer transistor 106).

The transfer gate 210 controls the transfer of photocurrent between the photodiode 104 and the n-type doping region 206 of the floating node 108. The transfer gate 210 may be energized (e.g., by applying a voltage or a current to the transfer gate 210) to cause a conductive channel to form in the substrate 202 between the photodiode 104 and the drain extension region 208. The conductive channel may be removed or closed by de-energizing the transfer gate 210, which blocks and/or prevents the flow of photocurrent between the photodiode 104 and the drain extension region 208. In some implementations, the transfer gate 210 includes a poly gate that includes polysilicon, a doped polysilicon (e.g., n⁺ doped polysilicon), or a combination thereof. In some implementations, the transfer gate 210 includes a metal gate that includes one or more metals.

The transfer gate 210 may be included in a dielectric layer 212 over the substrate 202. The dielectric layer 212 may include an intermetal dielectric (IMD) formed of an oxide material such as a silicon oxide (SiOₓ) (e.g., silicon dioxide (SiO₂)), a silicon nitride (SiNₓ), a silicon carbide (SiCₓ), a titanium nitride (TiNₓ), a tantalum nitride (TaNₓ), a hafnium oxide (HfOₓ), a tantalum oxide (TaOₓ), an aluminum oxide (AlOₓ), or another type of dielectric material.

A conductive structure 214 may be electrically connected to the n-type doping region 206 of the floating node 108 in order to allow for transfer of photocurrent out of the pixel sensor 200 and to a back end of line (BEOL). Similarly, a conductive structure 216 may be electrically connected to the transfer gate 210 to allow for energizing (and de-energizing) the transfer gate 210, as described above. The conductive structures 214 and 216 may include contact plugs, vias, and/or other types of structures. The conductive structures 214 and 216 may each be filled with a conductive material, such as tungsten, cobalt, ruthenium, and/or another type of conductive material.

A gate dielectric (also referred to as a “gate oxide”) 218 may be included above and/or over the top surface of the substrate 202. The gate dielectric 218 may include a dielectric material such as tetraethyl orthosilicate (TEOS) or another type of dielectric material.

The photodiode 104 of the pixel sensor 200 may be electrically and optically isolated from adjacent photodiodes by an isolation structure 220 (e.g., a DTI structure). The isolation structure 220 may surround the photodiode 104 as well as the p-type well 204, the n-type doping region 206, and the drain extension region 208. The isolation structure 220 may include a plurality of interconnecting trenches that extend into the substrate 202. The isolation structure 220 may provide optical isolation between the pixel sensor 200 and adjacent pixel sensors to reduce the amount of optical crosstalk between adjacent pixel sensors. In particular, the isolation structure 220 may absorb, refract, and/or reflect incident light, which may reduce the amount of incident light that travels through a pixel sensor 200 into an adjacent pixel sensor and is absorbed by the adjacent pixel sensor. Moreover, the isolation structure 220 may reflect incident light toward the photodiode 104, thereby increasing the amount of incident light that is absorbed by the photodiode 104 (which increases quantum efficiency (QE) of the pixel sensor 200).

The isolation structure 220 may be filled with a first dielectric material 222a. The first dielectric material 222a may be a high-k material exhibiting a permittivity of at least 7. For example, the first dielectric material 222a may be an aluminum oxide (e.g., Al₂O₃), a zirconium oxide (e.g., ZrO₂), a hafnium oxide (e.g., HfO₂), and/or another type of oxide material. Similarly, the isolation structure 220 may be filled with a second dielectric material 222b. The second dielectric material 222b may be a high-K material exhibiting a permittivity of at least 7. For example, the second dielectric material 222b may be an aluminum oxide (e.g., Al₂O₃), a zirconium oxide (e.g., ZrO₂), a hafnium oxide (e.g., HfO₂), and/or another type of oxide material. By selecting a permittivity of at least 7, optical isolation provided by the isolation structure 220 is increased—selecting a permittivity lower than 7 would degrade performance of the pixel sensor 200 by increasing optical crosstalk and reducing QE of the pixel sensor 200.

The isolation structure 220 may be a full DTI structure in that the isolation structure 220 extends through a full height of the substrate 202 from a first side (e.g., the top surface or front side) of the substrate 202 to a second side (e.g., the bottom surface or back side) of the substrate 202. In this way, the isolation structure 220 may absorb, refract, and/or reflect incident light along the full height or full thickness of the substrate 202, which further reduces optical crosstalk and further increases QE of the pixel sensor 200.

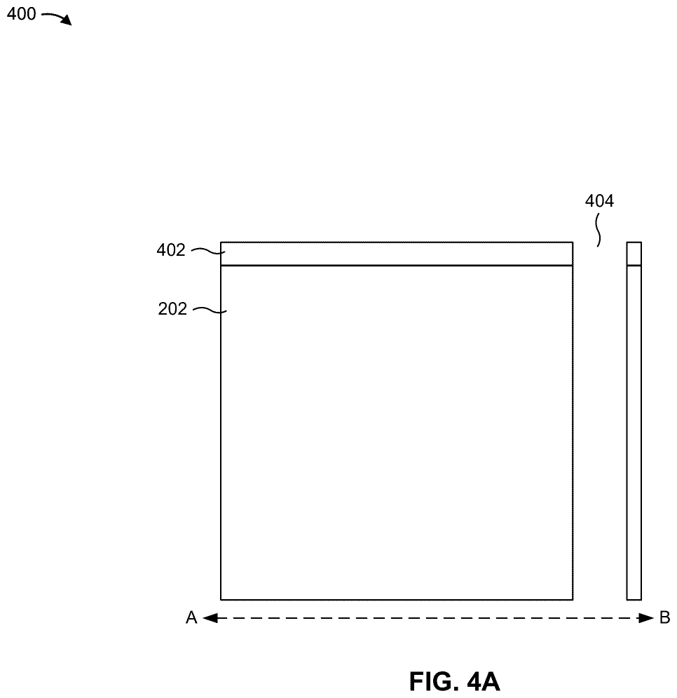

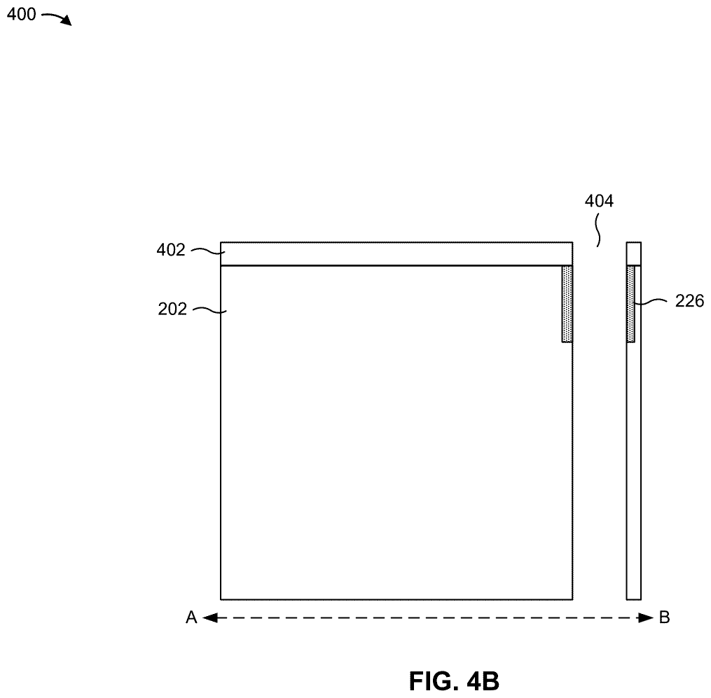

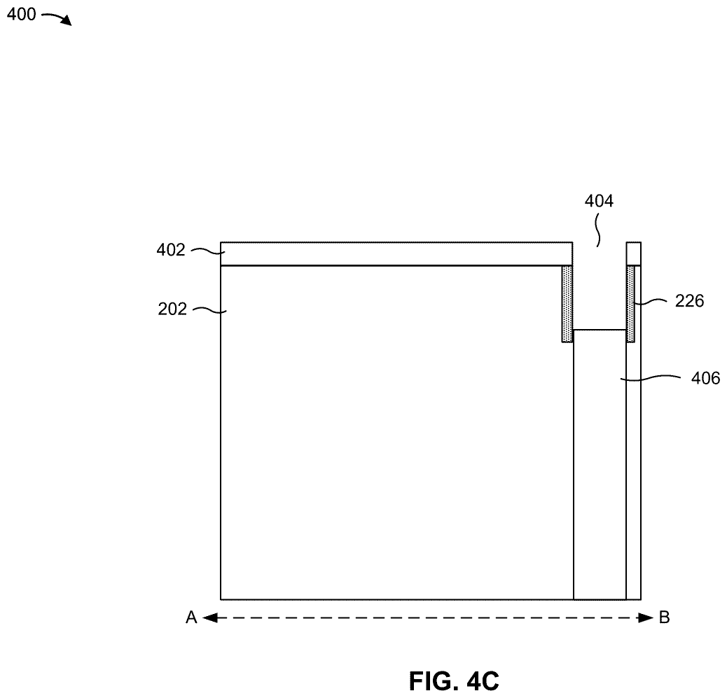

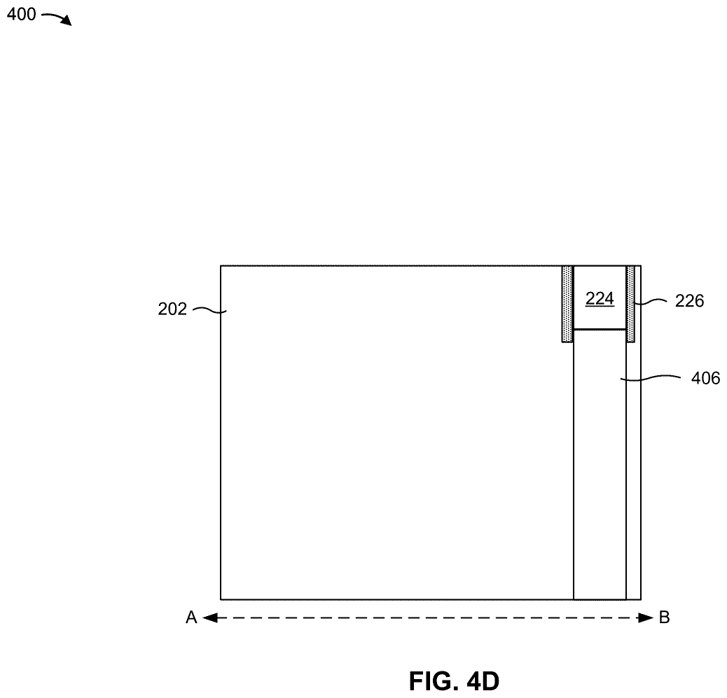

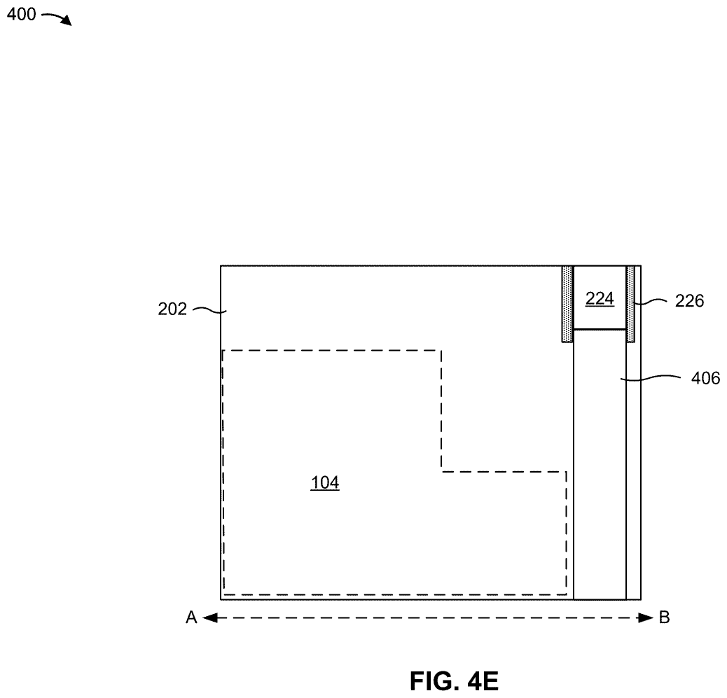

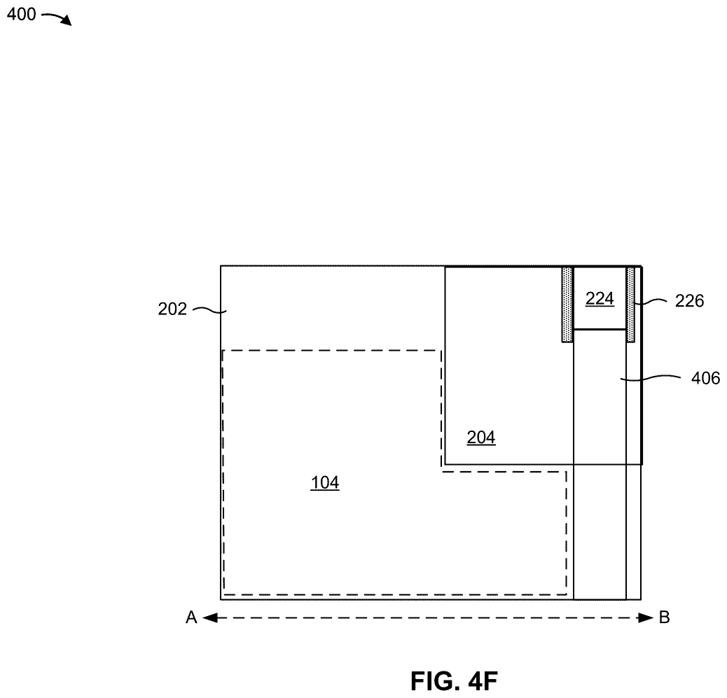

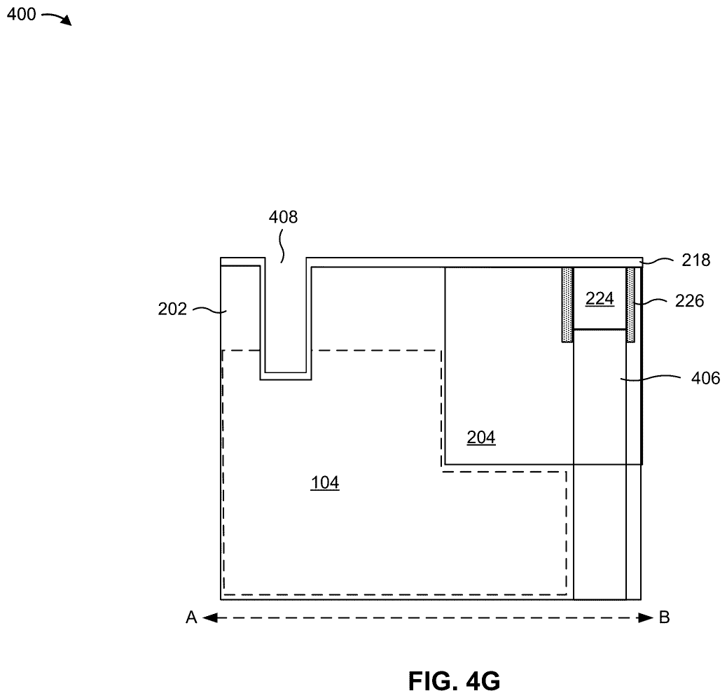

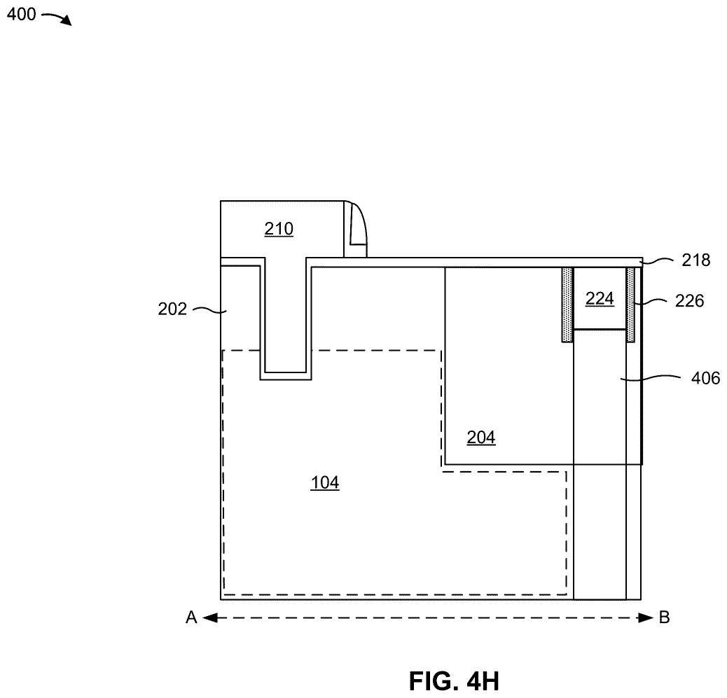

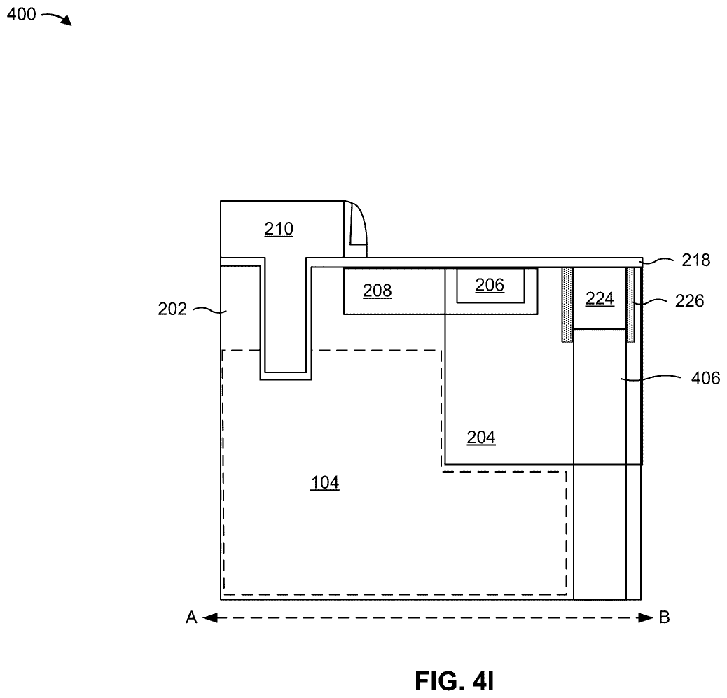

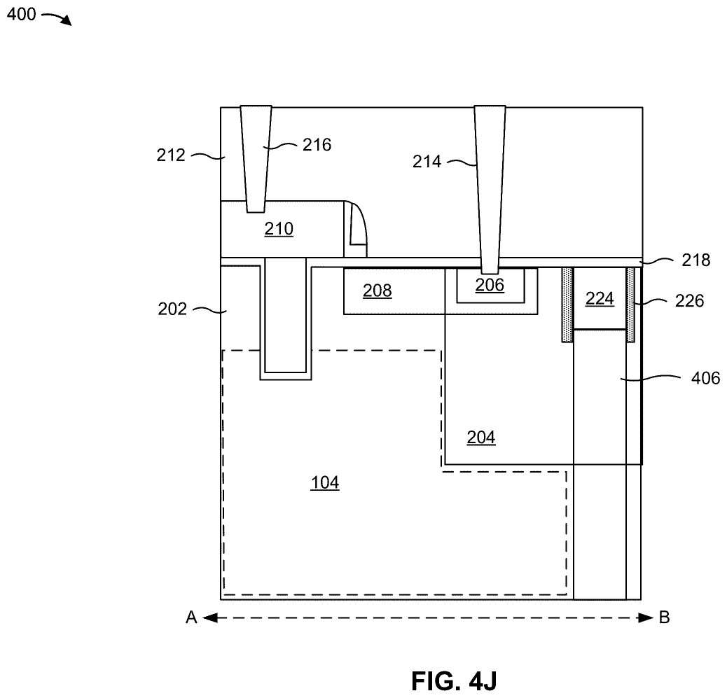

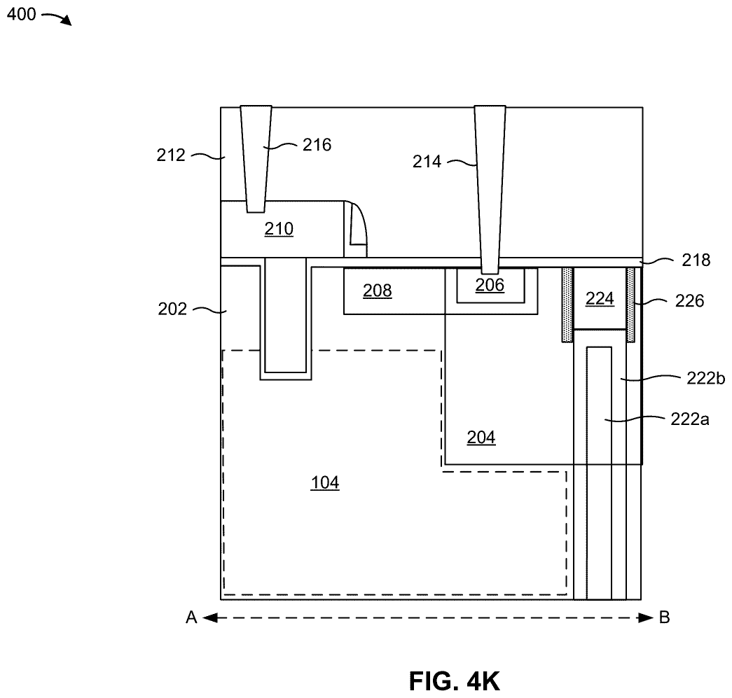

As further shown in FIG. 2A, a film 224 may function as a buffer between the isolation structure 220 and the gate dielectric 218. For example, the film 224 may protect the gate dielectric 218 during formation of the isolation structure 220 (e.g., as described in connection with FIG. 4J). The film 224 may include silicon dioxide, non-doped polysilicon, and/or a nitride material, among other examples. Accordingly, the film 224 may serve as a etch stop layer (ESL) to prevent etching into the gate dielectric 218.

In order to provide additional electrical isolation between the n-type doping region 206 of the floating node 108 and an adjacent pixel sensor, a p-type doping region 226 may be formed between the isolation structure 220 and the n-type doping region 206 (of the floating node 108). The p-type doping region 226 is also between the isolation structure 220 and the drain extension region 208 (associated with the transfer gate 210). The p-type doping region 226 prevents photocurrent from flowing through the isolation structure 220 (e.g., because dangling silicon bonds remaining after formation of the isolation structure 220 may allow for such flow). Additionally, the p-type doping region 226 absorbs extra electrons from dangling silicon bonds remaining after formation of the isolation structure 220, which decreases noise caused by the extra electrons that would otherwise alter the photocurrent.

The p-type doping region 226 may be formed using boron (B) as a dopant. The concentration associated with the p-type doping region 226 may is in a range from approximately 1.0×10¹⁷ inverse cubic centimeters (cm⁻³) to approximately 1.0×10²¹ cm⁻³. Selecting a concentration of at least 1.0×10¹⁷ cm⁻³ provides sufficient electrical isolation—selecting a smaller concentration would allow photocurrent to flow through the isolation structure 220. Selecting a concentration of no more than 1.0×10²¹ cm⁻³ reduces noise, caused by the extra holes in the p-type doping region 226, that can alter the photocurrent—selecting a larger concentration would allow the p-type doping region 226 to alter the photocurrent more significantly than extra electrons from dangling silicon bonds remaining after formation of the isolation structure 220.

FIG. 2B illustrates a top-down view of the pixel sensor 200. As shown in FIG. 2B, two photodiodes (associated with transfer gates 210a and 210b) may share an n-type doping region 206 (and thus share a floating node 108). The isolation structure 220 surrounds the photodiodes and isolates the photodiodes from adjacent pixel sensors. The cross-section depicted in FIG. 2A may be along the A-B line shown in FIG. 2B.

FIG. 2C illustrates a cross-section view of a pixel sensor 230. The pixel sensor 230 is similar to the pixel sensor 200 of FIG. 2A except that the pixel sensor 230 includes a first film 232 and a second film 234. The films 232 and 234 function as a buffer between the isolation structure 220 and the gate dielectric 218. The first film 232 and the second film 234 may each include silicon dioxide, non-doped polysilicon, and/or a nitride material, among other examples. Accordingly, the films 232 and 234 may serve as a multi-layer ESL to prevent etching into the gate dielectric 218. A top-down view of the pixel sensor 230 would be similar to the top-down view of the pixel sensor 200 shown in FIG. 2B.

As indicated above, FIGS. 2A-2C are provided as examples. Other examples may differ from what is described with regard to FIGS. 2A-2C.

FIG. 2D illustrates a cross-section view of a pixel sensor 260. The pixel sensor 260 is similar to the pixel sensor 230 of FIG. 2B except that the first film 232 of the pixel sensor 260 is part of the n-type doping region 206. Therefore, the second film 234 function as a buffer between the isolation structure 220 and the first film 232. The first film 232 may include n-type doped polysilicon (e.g., phosphorus-doped) or epitaxial silicon with n-type doping (e.g., phosphorus doping), among other examples. The concentration associated with the first film 232 may is in a range from approximately 1.0×10¹⁸ cm⁻³ to approximately 1.0×10²² cm⁻³. Selecting a concentration of at least 1.0×10¹⁸ cm⁻³ provides sufficient drain functionality-selecting a smaller concentration would impede photocurrent flowing through the n-type doping region 206. Selecting a concentration of no more than 1.0×10²² cm⁻³ increases stability and reduces electrons that migrate to other portions of the pixel sensor 260—selecting a larger concentration would allow electrons to migrate to other portions of the pixel sensor 260 and disrupt performance of the pixel sensor 260 (e.g., by migrating to, and thus reducing QE of, the photodiode 104).

FIG. 2E illustrates a top-down view of the pixel sensor 260. As shown in FIG. 2E, four photodiodes (associated with transfer gates 210a, 210b, 210c, and 210d) may share an n-type doping region 206 (and thus share a floating node 108). The isolation structure 220 surrounds the photodiodes and isolates the photodiodes from adjacent pixel sensors. The cross-section depicted in FIG. 2D may be along the A-B line shown in FIG. 2E.

As indicated above, FIGS. 2D-2E are provided as an example. Other examples may differ from what is described with regard to FIGS. 2D-2E.

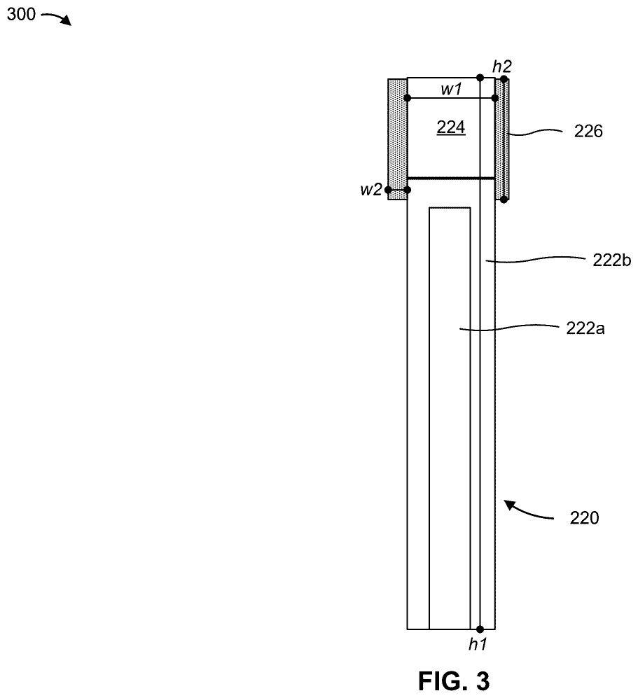

FIG. 3 illustrates a cross-section of an isolation structure. The isolation structure 220 is shown with reference to the pixel sensor 200 of FIG. 2A; however, the isolation structure 220 may be similarly included in the pixel sensor 230 of FIG. 2C or the pixel sensor 260 of FIG. 2D.

As shown in FIG. 3, a ratio of a depth (e.g., represented by h1) associated with the isolation structure 220 to a depth (e.g., represented by h2) of the p-type doping region 226 may be in a range from approximately 2.50 to approximately 266.67. For example, the depth h1 may be in a range from approximately 2.5 micrometers (μm) to approximately 8.0 μm, and the depth h2 may be in a range from approximately 30 nanometers (nm) to approximately 1.0 μm. Selecting a ratio of at least 2.50 reduces (or even eliminates) electrons that migrate from the n-type doping region 206 to the photodiode 104 (not shown)—selecting a smaller ratio would allow electrons to migrate and disrupt performance of the pixel sensor (e.g., by migrating to, and thus reducing QE of, the photodiode 104). Selecting a ratio of no more than 266.67 reduces a thickness of the substrate 202 (not shown)—using a thicker substrate would reduce QE of the pixel sensor by resulting in longer light paths for incident light to the photodiode 104 and/or longer electrical paths for the photocurrent to the floating node 108 (not shown).

Additionally, a ratio of a width (e.g., represented by w/in FIG. 3) associated with the isolation structure 220 to a width (e.g., represented by w2 in FIG. 3) of the p-type doping region is in a range from approximately 1.0 to approximately 60.0. For example, the width w/may be in a range from approximately 50 nm to approximately 300 nm, and the width w2 may be in a range from approximately 5 nm to approximately 50 nm. Selecting a ratio of at least 1.0 reduces noise, caused by the extra holes in the p-type doping region 226, that can alter the photocurrent—selecting a larger ratio would allow the p-type doping region 226 to alter the photocurrent more significantly than extra electrons from dangling silicon bonds remaining after formation of the isolation structure 220. Selecting a ratio of no more than 60.0 isolates the n-type doping region 206 (not shown) from adjacent pixel sensors—selecting a smaller ratio would allow photocurrent to flow through the isolation structure 220.

In some implementations, the film 224 may have a depth equal to, or smaller than, the depth of the p-type doping region 226. For example, the film 224 may have a depth in a range from approximately 25 nm to approximately 200 nm.

As indicated above, FIG. 3 is provided as an example. Other examples may differ from what is described with regard to FIG. 3. For example, the film 224 may be replaced with a first film 232 and a second film 234, as described in connection with FIG. 2C. Therefore, the films 232 and 234 may have a joint depth that is equal to, or smaller than, the depth of the film 224 and may have a width that is approximately equal to (e.g., within 1%, 10%, or a similar margin of error) the width of the film 224. Alternatively, the film 224 may be replaced with a first film 232 and a second film 234, as described in connection with FIG. 2D. Therefore, the first film 232 may have a width that is equal to, or larger than, a combined width of the isolation structure 220 and the p-type doping region 226. For example, the width may be in a range from approximately 60 nm to approximately 500 nm. Selecting a width of at least 60 nm allows for electrons to flow from the photodiode 104 (not shown) to the n-type doping region 206 (not shown) that includes the first film 232—selecting a smaller width would impede photocurrent flowing through the n-type doping region 206. Selecting a width of no more than 500 nm reduces electrons that migrate to other portions of the pixel sensor—selecting a larger width would allow electrons to migrate to other portions of the pixel sensor and disrupt performance of the pixel sensor (e.g., by migrating to, and thus reducing QE of, the photodiode 104).

FIGS. 4A-4K are diagrams of an example implementation 400 described herein. Example implementation 400 may be an example process for forming the pixel sensor 200 of FIG. 2A with a p-type doping region adjacent to an isolation structure. The pixel sensor formed using example implementation 400 may be included in a CMOS image sensor, a BSI CMOS image sensor, or another type of image sensor.

As shown in FIG. 4A, the example process for forming the pixel sensor may be performed in connection with a substrate 202. As described above, the substrate 202 may include a semiconductor die substrate, a semiconductor wafer, a stacked semiconductor wafer, or another type of substrate in which semiconductor pixels may be formed. For example, the substrate 202 may be formed of silicon (Si) (e.g., a silicon substrate), a material including silicon, a III-V compound semiconductor material such as gallium arsenide (GaAs), an SOI, or another type of semiconductor material that is capable of generating a charge from photons of incident light. In some implementations, the substrate 202 is formed of a doped material (e.g., a p-doped material or an n-doped material) such as a doped silicon.

As further shown in FIG. 4A, a hardmask (HM) 402 may be formed over the substrate 202. For example, a deposition tool may form the HM 402 over and/or on the frontside surface of the substrate 202. In some implementations, a deposition tool forms the HM 402 using a spin-coating technique, a chemical vapor deposition (CVD) technique, a physical vapor deposition (PVD) technique, an atomic layer deposition (ALD) technique, and/or another deposition technique. Furthermore, an exposure tool may expose the HM 402 to a radiation source to form a pattern on the HM 402, and a developer tool may develop and remove portions of the HM 402 to expose the pattern. An etch tool may etch a portion of the substrate 202 according to the pattern to form a recess 404. For example, an etch tool may use a wet etch technique, a dry etch technique, a plasma-enhanced etch technique, and/or another type of etch technique to etch substrate 202.

In order to repair some damage caused by formation of the recess 404, an annealing process may be performed. For example, an annealing tool may heat the substrate 202 for an amount of time that satisfies a threshold (e.g., associated with DTI damage repair). The annealing process may reduce a quantity of dangling silicon bonds that were caused by etching the substrate 202.

As shown in FIG. 4B, a p-type doping region 226 may be formed adjacent to a top portion of the recess 404. For example, an ion implantation tool may dope top surfaces of the recess 404 to form the p-type doping region 226. An ion implantation tool may implant an n-type dopant (e.g., boron) using implantation, plasma doping, and/or laser doping (e.g., using borosilicate glass).

As shown in FIG. 4C, the recess 404 may be filled with a dummy material 406. The dummy material 406 may include an oxide material and/or another type of dielectric material. A deposition tool may deposit the dummy material 406 using a spin-coating technique, a CVD technique, a PVD technique, an ALD technique, and/or another deposition technique. In some implementations, the recess 404 is only partially filled (e.g., such that a top surface of the dummy material 406 is below a top surface of the substrate 202 but above a bottom boundary of the p-type doping region 226, as shown in FIG. 4C). Alternatively, the dummy material 406 may overflow the recess 404 such that a planarization tool removes excess dummy material (e.g., using a chemical mechanical planarization (CMP) technique), and an etch tool etches the dummy material 406 back (e.g., such that a top surface of the dummy material 406 is below the top surface of the substrate 202 but above the bottom boundary of the p-type doping region 226, as shown in FIG. 4C).

As shown in FIG. 4D, a film 224 may be formed in the recess 404. For example, a deposition tool may form the film 224 over the dummy material 406. In some implementations, a deposition tool forms the film 224 using a spin-coating technique, a CVD technique, a PVD technique, an ALD technique, and/or another deposition technique. The film 224 may overflow the recess 404 such that a planarization tool removes excess material (e.g., using a CMP technique), and a top surface of the film 224 is approximately level (e.g., within 1%, 10%, or a similar margin of error) with a top surface of the substrate 202. The dummy material 406 and the film 224 may function as a dummy isolation structure.

As further shown in FIG. 4D, the HM 402 may be removed. For example, a photoresist removal tool may remove remaining portions of the HM 402 using a chemical stripper, a plasma asher, and/or another technique. Although the example implementation 400 includes the HM 402 being removed after the film 224 is formed, other implementations may include the HM 402 being removed before the film 224 is formed (e.g., after the dummy material 406 is deposited or after the p-type doping region 226 is implanted).

As shown in FIG. 4E, a photodiode 104 may be formed in the substrate 202. For example, an ion implantation tool may dope one or more portions of the substrate 202, using an ion implantation technique, to form n-type regions and/or p-type regions of the photodiode 104 to form a p-n junction for the photodiode 104. For example, an ion implantation tool may dope the substrate 202 with an n-type dopant to form an n-type region and may dope the substrate 202 with a p-type dopant to form a p-type portion of the p-n junction. In some implementations, another technique is used to form the photodiode 104, such as diffusion.

As shown FIG. 4F, a p-type well 204 may be formed adjacent to the photodiode 104 and the transfer gate 210 (as well as adjacent to the dummy isolation structure). For example, an ion implantation tool may dope a portion of the substrate 202 to form the p-type well 204. An ion implantation tool may implant p⁺ ions in the substrate 202 to form the p-type well 204. In some implementations, the p-type well 204 is formed via diffusion and/or epitaxial growth.

As shown in FIG. 4G, a recess 408 may be formed in the substrate 202. The recess 408 may expose (or at least be over) a top boundary of the photodiode 104. A deposition tool may form a photoresist layer over and/or on the frontside surface of the substrate 202, an exposure tool may expose the photoresist layer to a radiation source to form a pattern on the photoresist layer, and a developer tool may develop and remove portions of the photoresist layer to expose the pattern. Accordingly, an etch tool may etch a portion of the substrate 202 according to the pattern to form the recess 408. For example, an etch tool may use a wet etch technique, a dry etch technique, a plasma-enhanced etch technique, and/or another type of etch technique to etch the substrate 202. A photoresist removal tool may remove the remaining portions of the photoresist layer (e.g., using a chemical stripper, a plasma asher, and/or another technique) after the recess 408 is formed.

As further shown in FIG. 4G, a gate dielectric 218 may be formed over and/or on the top surface of the substrate 202. The gate dielectric 218 may be formed over sidewalls and a bottom surface of the recess 408 in addition to the top surface of the substrate 202. A deposition tool may deposit the gate dielectric 218 using a CVD technique, a PVD technique, an ALD technique, and/or another type of deposition technique. In some implementations, a planarization tool may planarize the gate dielectric 218 (e.g., using a CMP technique) after the gate dielectric 218 is deposited.

As shown in FIG. 4H, the transfer gate 210 may be formed over and/or on the gate dielectric 218 as well as in the recess 408. In some implementations, a deposition tool deposits the transfer gate 210 using a CVD technique, a PVD technique, an ALD technique, and/or another type of deposition technique, and/or a plating tool deposits the transfer gate 210 using an electroplating operation. In some implementations, an ion implantation tool may form the transfer gate 210 using one or more ion implantation operations.

As shown in FIG. 4I, a drain extension region 208 may be formed adjacent to (and thus associated with) the transfer gate 210. For example, an ion implantation tool may dope a portion of the top surface of the substrate 202 to form the drain extension region 208. An ion implantation tool may implant n⁺ ions in the substrate 202 to form the drain extension region 208. In some implementations, the drain extension region 208 is formed via diffusion or epitaxial growth. The drain extension region 208 may be formed between the transfer gate 210 and a sidewall of the transfer gate 210 using lithography to define a location of the drain extension region 208.

As further shown FIG. 4I, an n-type doping region 206 may be formed adjacent to the photodiode 104 and the transfer gate 210 (as well as adjacent to the dummy isolation structure). For example, an ion implantation tool may dope a portion of the substrate 202 to form the n-type doping region 206. An ion implantation tool may implant n⁺ ions in the substrate 202 to form the n-type doping region 206. In some implementations, the n-type doping region 206 is formed via diffusion and/or epitaxial growth.

As shown in FIG. 4J, a dielectric layer 212 may be formed over the substrate 202. A deposition tool may deposit the dielectric layer 212 using a CVD technique, a PVD technique, an ALD technique, and/or another type of deposition technique. In some implementations, a planarization tool may planarize the dielectric layer 212 (e.g., using a CMP technique) after the dielectric layer 212 is deposited. Additionally, as shown in FIG. 4I, a conductive structure 214 may be formed to contact the n-type doping region 206. The conductive structure 214 may be formed by etching a recess in the dielectric layer 212 (e.g., similarly as described above) and depositing conductive material (e.g., copper (Cu)) in the recess. Similarly, a conductive structure 216 may be formed to contact the transfer gate 210). The conductive structures 214 and 216 may connect to a BEOL. For example, the structure shown in FIG. 4I may be bonded to an additional chip including the BEOL (e.g., an ASIC 118, as described in connection with FIG. 1A). In implementations where pixel transistors (e.g., the reset gate 110, the SF transistor 112, and the RS transistor 114) are on a separate chip from the photodiode 104, the chips may be bonded together such that a combined structured is bonded to the additional chip including the BEOL.

As shown in FIG. 4K, the dummy material 406 may be removed and replaced with dielectric materials 222a and 222b. For example, an etch tool may use a wet etch technique, a dry etch technique, a plasma-enhanced etch technique, and/or another type of etch technique to remove the dummy material 406. Additionally, a deposition tool may deposit the dielectric materials 222a and 222b using a CVD technique, a PVD technique, an ALD technique, and/or another type of deposition technique. The dielectric materials 222a and 222b may function as an isolation structure with the film 224.

As indicated above, FIGS. 4A-4K are provided as an example. Other examples may differ from what is described with regard to FIGS. 4A-4K. For example, the recess 404 may be formed using a plurality of layers rather than a single HM layer. The plurality of layers may include a bottom layer, a middle layer, and a photoresist layer. Additionally, or alternatively, a sidewall may be formed on the transfer gate 210 (e.g., after formation of the drain extension region 208).

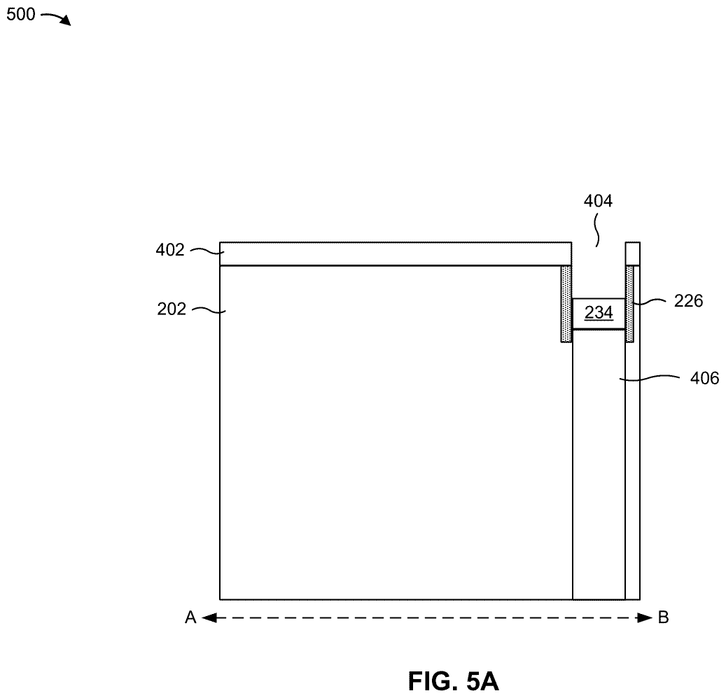

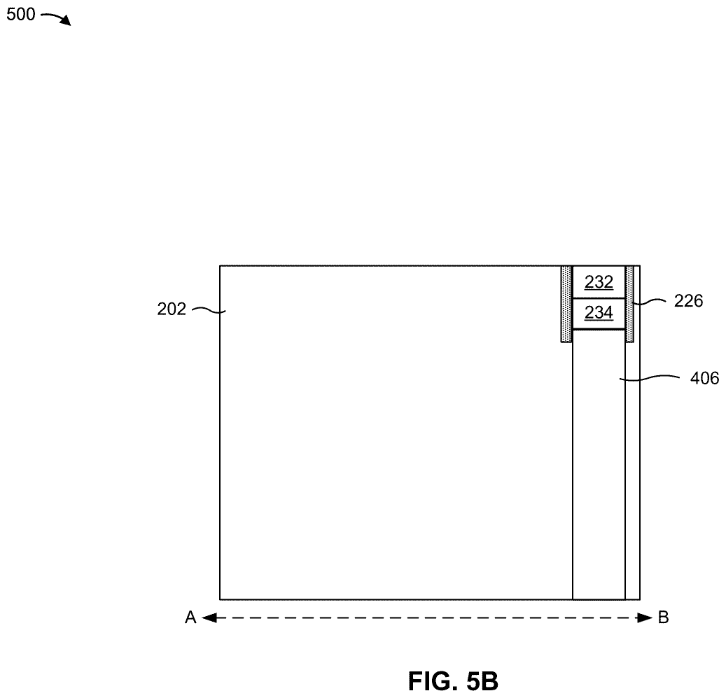

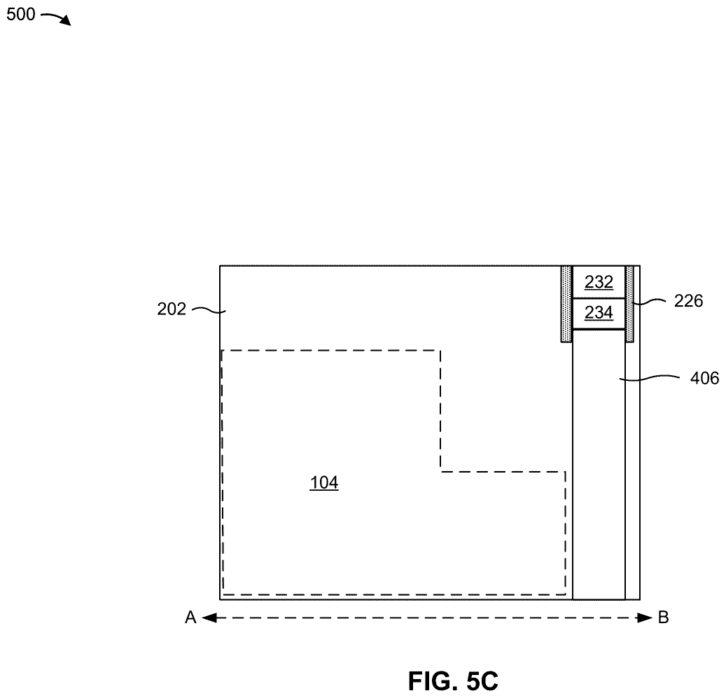

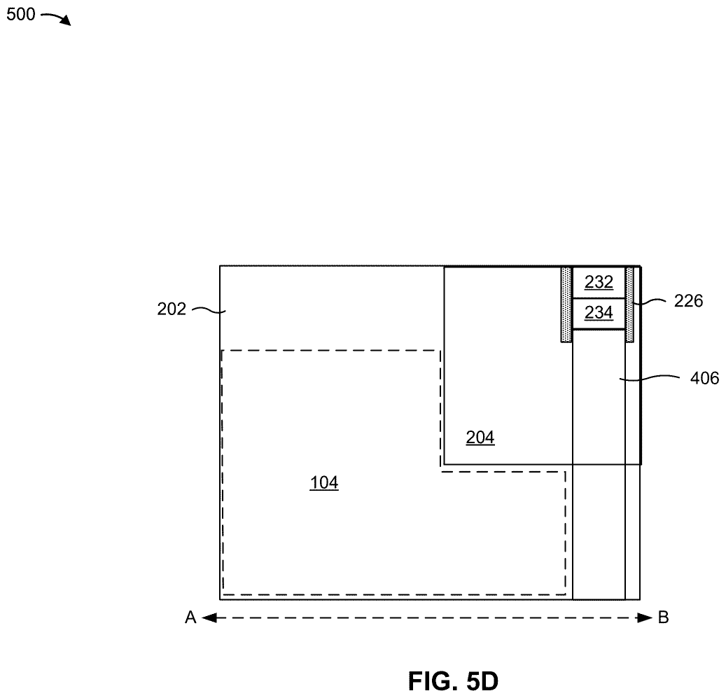

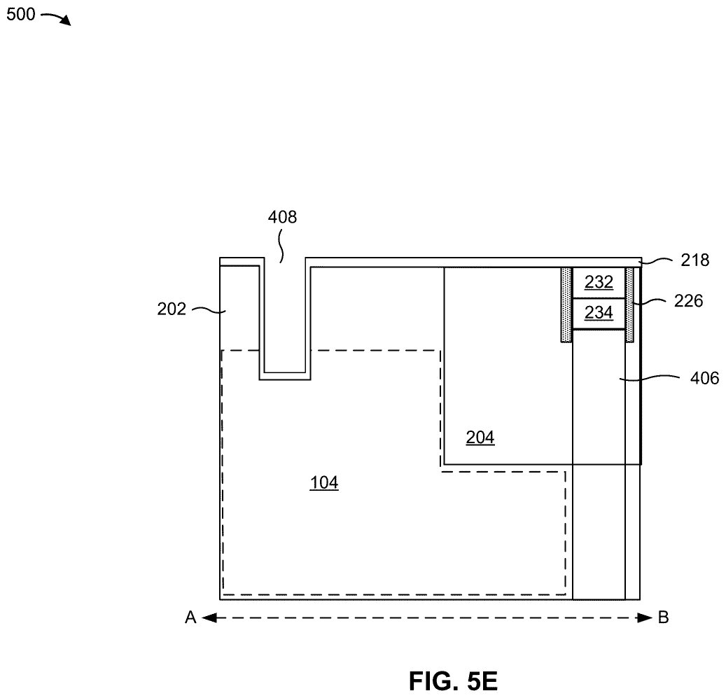

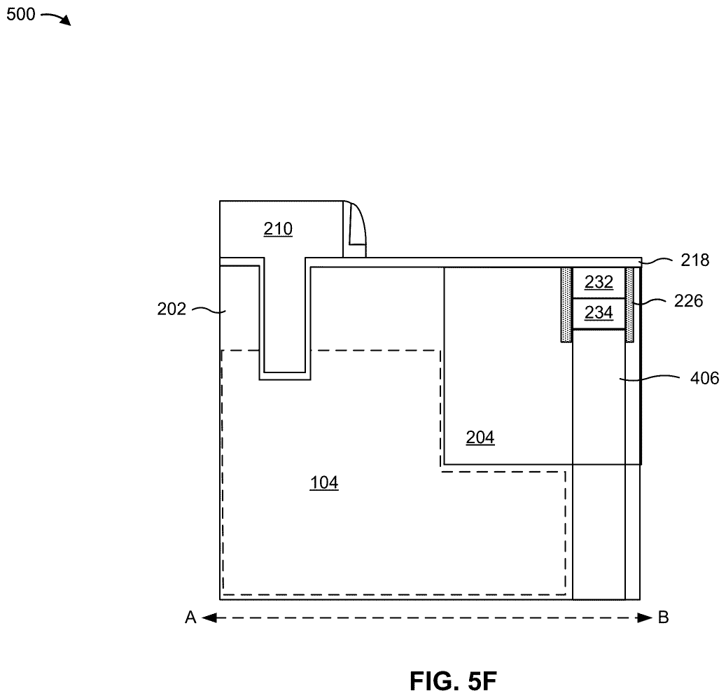

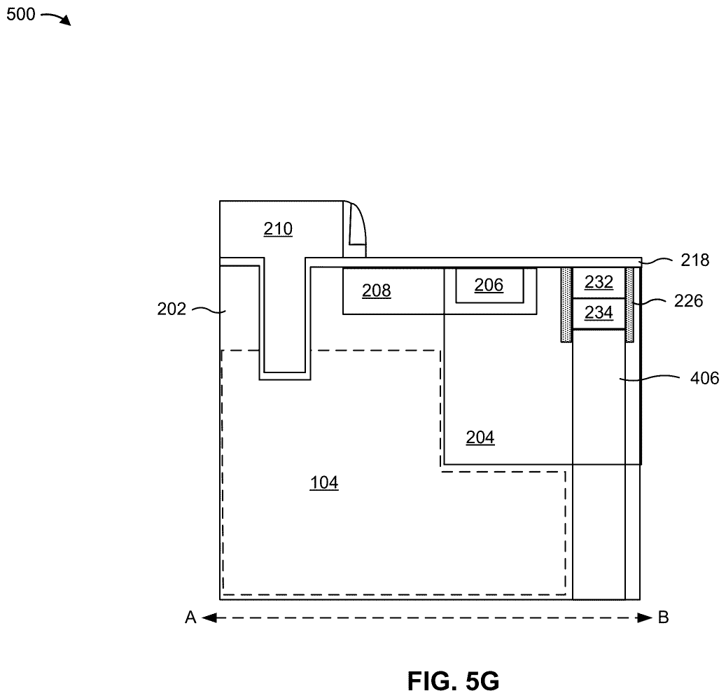

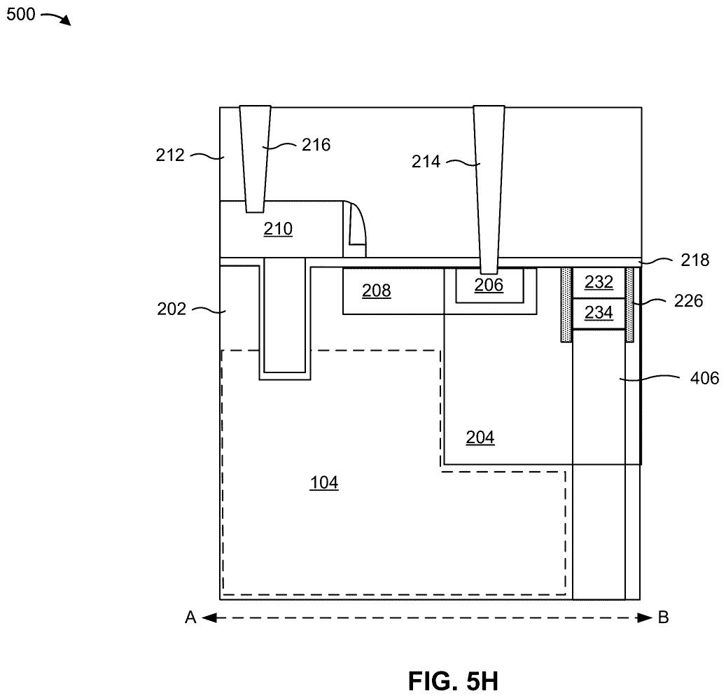

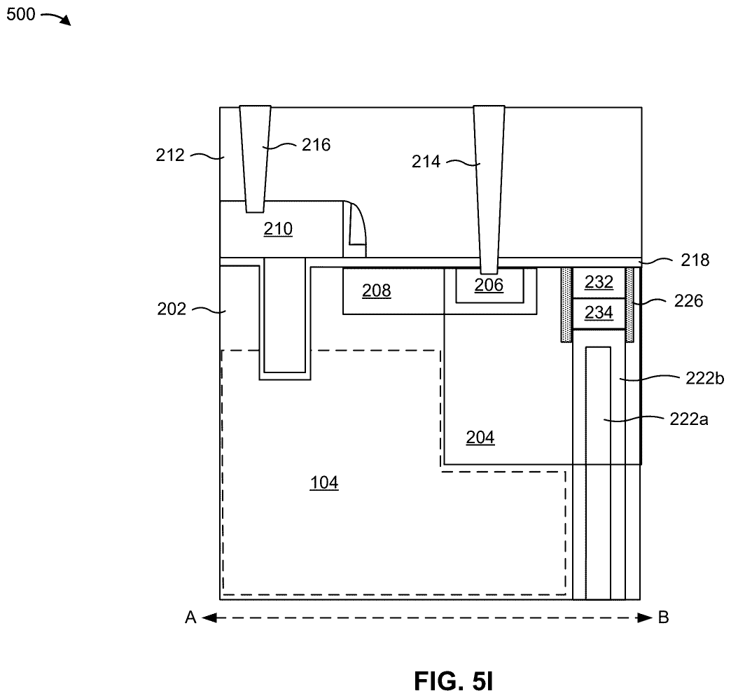

FIGS. 5A-5I are diagrams of an example implementation 500 described herein. Example implementation 500 may be an example process for forming the pixel sensor 230 of FIG. 2C with a p-type doping region adjacent to an isolation structure. The pixel sensor formed using example implementation 500 may be included in a CMOS image sensor, a BSI CMOS image sensor, or another type of image sensor.

As shown in FIG. 5A, the example implementation 500 may include processes described in connection with FIGS. 4A-4C. As further shown in FIG. 5A, a film 234 may be formed in the recess 404. For example, a deposition tool may form the film 234 over the dummy material 406. In some implementations, a deposition tool forms the film 234 using a spin-coating technique, a CVD technique, a PVD technique, an ALD technique, and/or another deposition technique. In some implementations, the recess 404 is only partially filled (e.g., such that a top surface of the film 234 is below a top surface of the substrate 202 but above a bottom boundary of the p-type doping region 226, as shown in FIG. 5A). Alternatively, the film 234 may overflow the recess 404 such that a planarization tool removes excess film (e.g., using a CMP technique), and an etch tool etches the film 234 back (e.g., such that a top surface of the film 234 is below the top surface of the substrate 202 but above the bottom boundary of the p-type doping region 226, as shown in FIG. 5A).

As shown in FIG. 5B, a film 232 may be formed in the recess 404. For example, a deposition tool may form the film 232 over the film 234. In some implementations, a deposition tool forms the film 232 using a spin-coating technique, a CVD technique, a PVD technique, an ALD technique, and/or another deposition technique. The film 232 may overflow the recess 404 such that a planarization tool removes excess material (e.g., using a CMP technique), and a top surface of the film 232 is approximately level (e.g., within 1%, 10%, or a similar margin of error) with a top surface of the substrate 202. The dummy material 406, the film 234, and the film 232 may function as a dummy isolation structure.

As further shown in FIG. 5B, the HM 402 may be removed. For example, the HM 402 may be removed as described in connection with FIG. 4D.

As shown in FIG. 5C, a photodiode 104 may be formed in the substrate 202. For example, the photodiode 104 may be implanted as described in connection with FIG. 4E.

As shown FIG. 5D, a p-type well 204 may be formed adjacent to the photodiode 104 and the transfer gate 210 (as well as adjacent to the dummy isolation structure). For example, the p-type well 204 may be formed as described in connection with FIG. 4F.

As shown in FIG. 5E, a recess 408 may be formed in the substrate 202. The recess 408 may be formed as described in connection with FIG. 4G. As further shown in FIG. 5E, a gate dielectric 218 may be formed over and/or on the top surface of the substrate 202. The gate dielectric 218 may be formed as described in connection with FIG. 4G.

As shown in FIG. 5F, the transfer gate 210 may be formed over and/or on the gate dielectric 218 as well as in the recess 408. For example, the transfer gate 210 may be formed as described in connection with FIG. 4H.

As shown in FIG. 5G, a drain extension region 208 may be formed adjacent to (and thus associated with) the transfer gate 210. For example, the drain extension region 208 may be implanted as described in connection with FIG. 4I. As further shown FIG. 5G, an n-type doping region 206 may be formed adjacent to the photodiode 104 and the transfer gate 210 (as well as adjacent to the dummy isolation structure). For example, the n-type doping region 206 may be implanted as described in connection with FIG. 4I.

As shown in FIG. 5H, a dielectric layer 212 may be formed over the substrate 202. The dielectric layer 212 may be deposited as described in connection with FIG. 4J. Additionally, as shown in FIG. 5G, a conductive structure 214 may be formed to contact the n-type doping region 206, and a conductive structure 216 may be formed to contact the transfer gate 210). The conductive structures 214 and 216 may connect to a BEOL. For example, the structure shown in FIG. 5H may be bonded to an additional chip including the BEOL (e.g., an ASIC 118, as described in connection with FIG. 1A). In implementations where pixel transistors (e.g., the reset gate 110, the SF transistor 112, and the RS transistor 114) are on a separate chip from the photodiode 104, the chips may be bonded together such that a combined structured is bonded to the additional chip including the BEOL.

As shown in FIG. 5I, the dummy material 406 may be removed and replaced with dielectric materials 222a and 222b. Accordingly, the dielectric materials 222a and 222b may function as an isolation structure with the films 232 and 234.

As indicated above, FIGS. 5A-5I are provided as an example. Other examples may differ from what is described with regard to FIGS. 5A-5I. For example, the recess 404 may be formed using a plurality of layers rather than a single HM layer. The plurality of layers may include a bottom layer, a middle layer, and a photoresist layer. Additionally, or alternatively, a sidewall may be formed on the transfer gate 210 (e.g., after formation of the drain extension region 208).

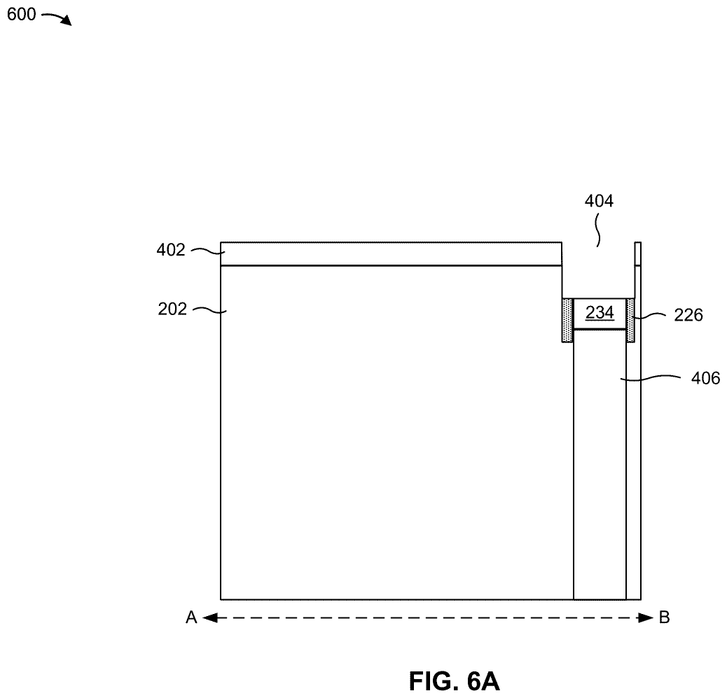

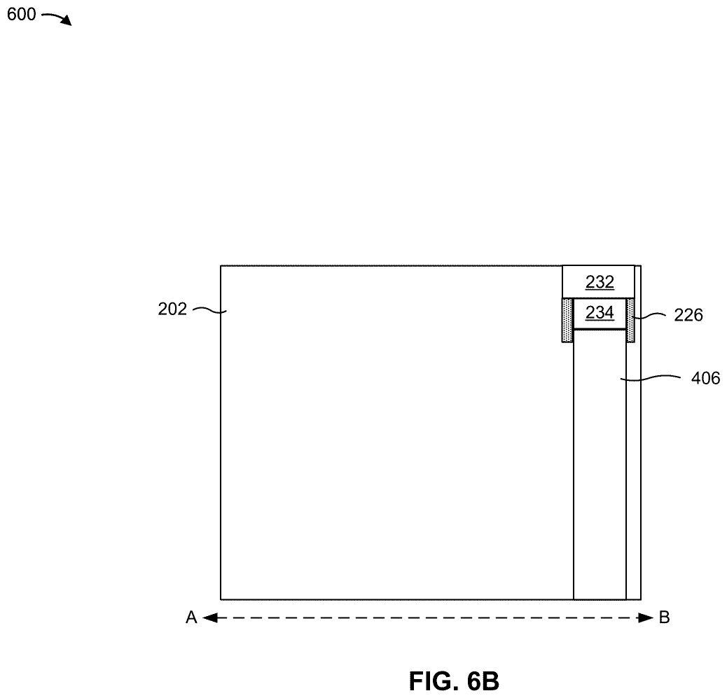

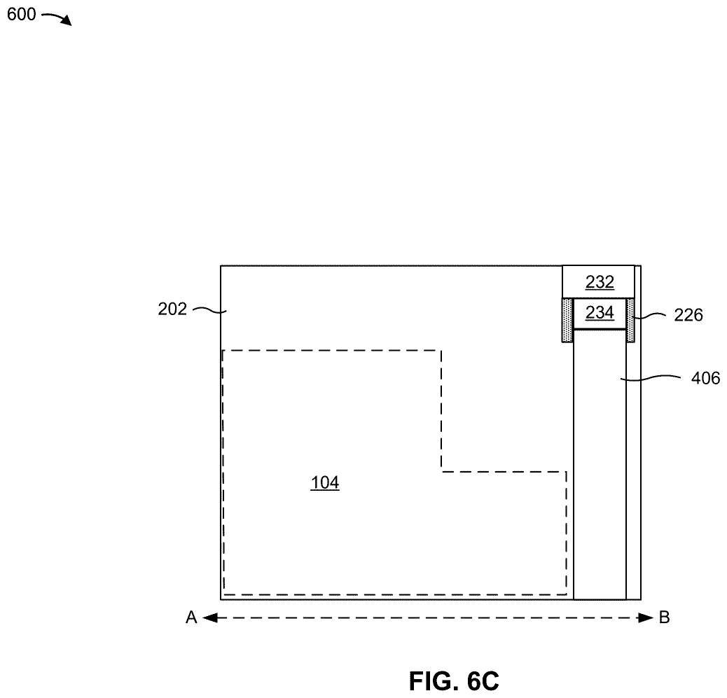

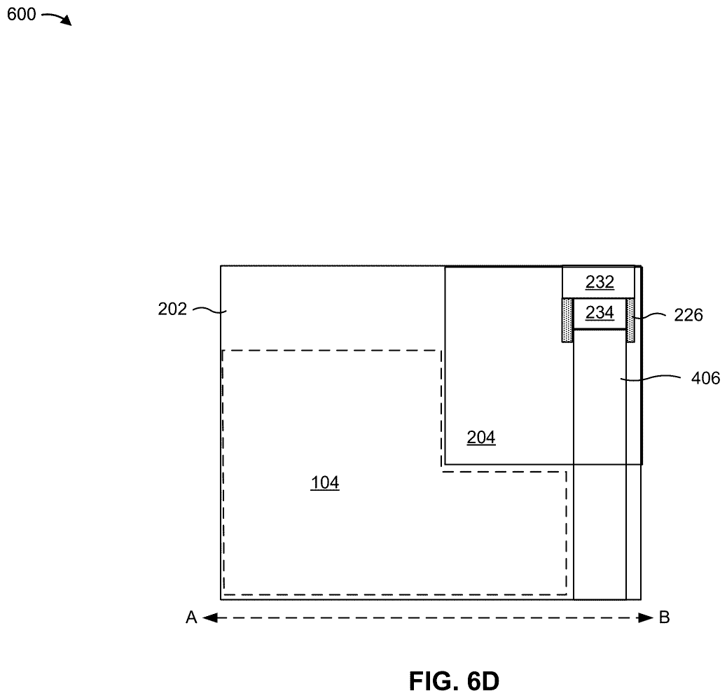

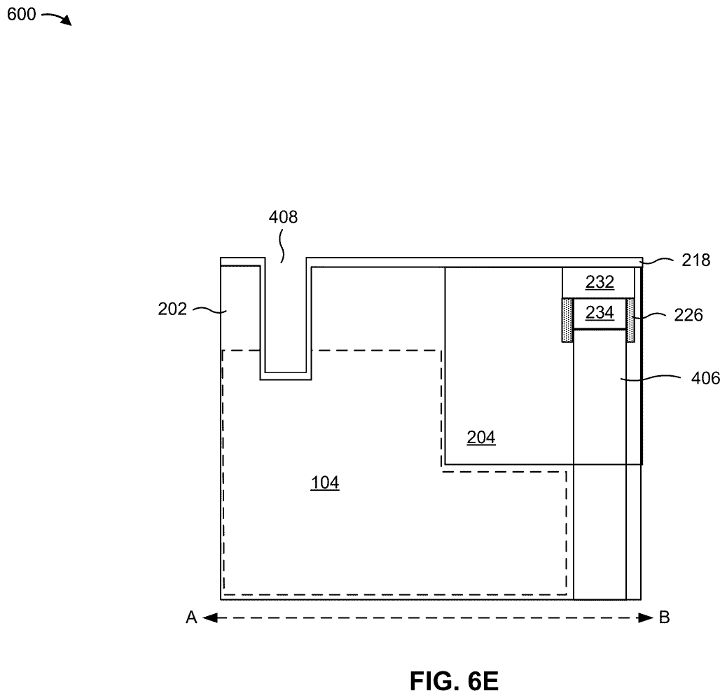

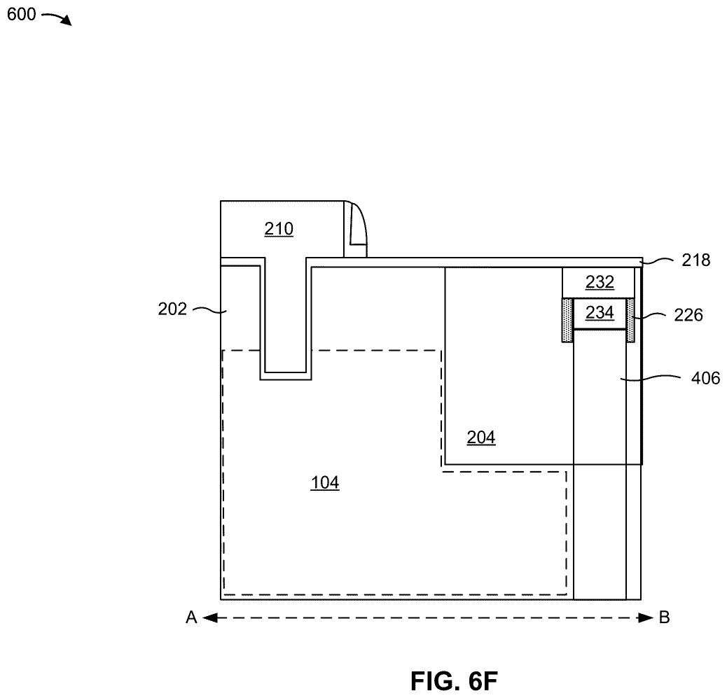

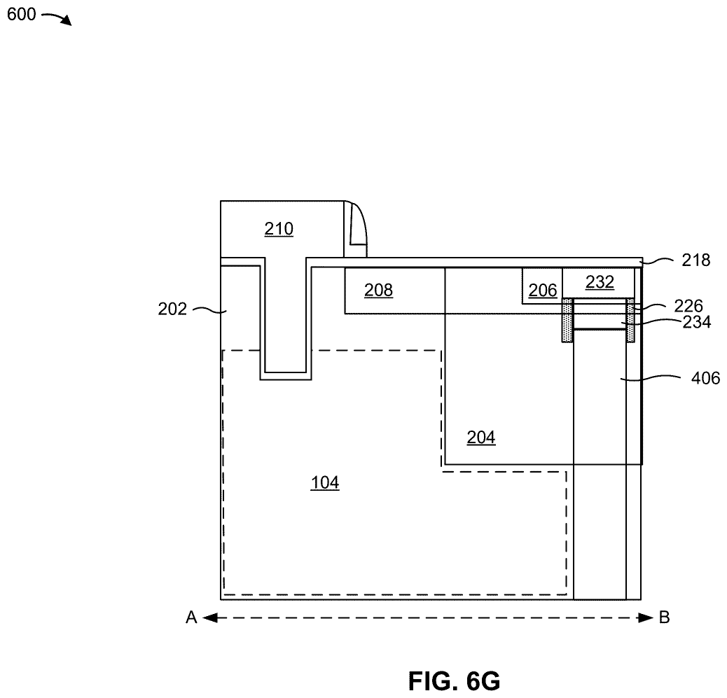

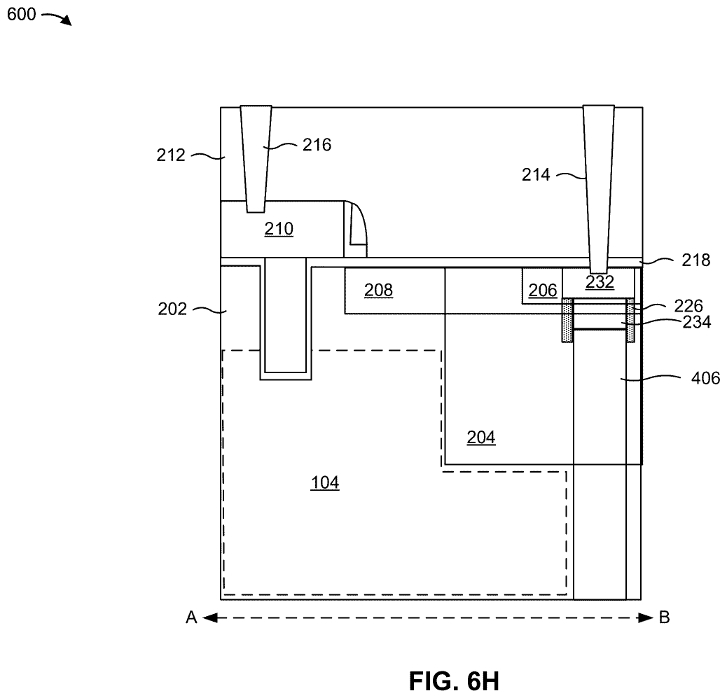

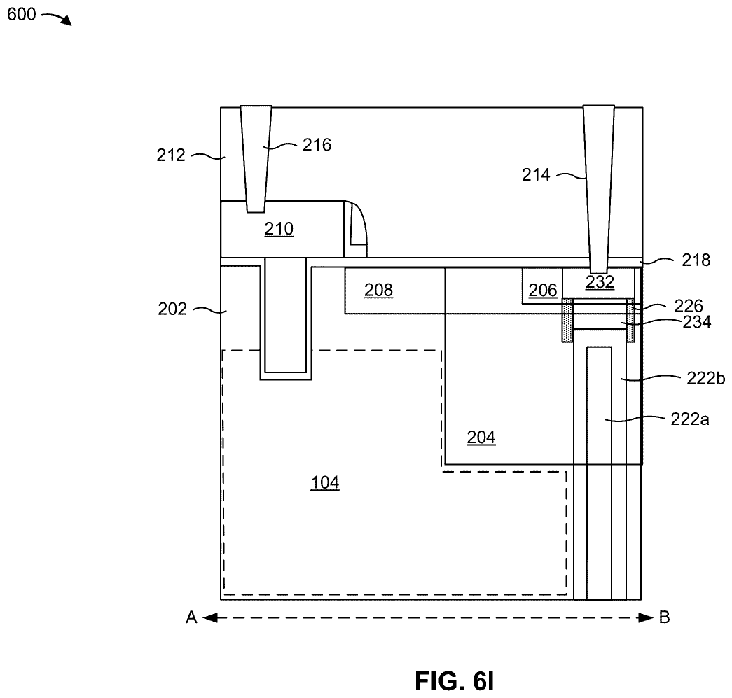

FIGS. 6A-6I are diagrams of an example implementation 600 described herein. Example implementation 600 may be an example process for forming the pixel sensor 260 of FIG. 2D with a p-type doping region adjacent to an isolation structure. The pixel sensor formed using example implementation 600 may be included in a CMOS image sensor, a BSI CMOS image sensor, or another type of image sensor.

As shown in FIG. 6A, the example implementation 600 may include processes described in connection with FIGS. 4A-4C. As further shown in FIG. 6A, a film 234 may be formed in the recess 404. For example, a deposition tool may form the film 234 over the dummy material 406. In some implementations, a deposition tool forms the film 234 using a spin-coating technique, a CVD technique, a PVD technique, an ALD technique, and/or another deposition technique. In some implementations, the recess 404 is only partially filled (e.g., such that a top surface of the film 234 is below a top surface of the substrate 202 but above a bottom boundary of the p-type doping region 226, as shown in FIG. 6A). Alternatively, the film 234 may overflow the recess 404 such that a planarization tool removes excess film (e.g., using a CMP technique), and an etch tool etches the film 234 back (e.g., such that a top surface of the film 234 is below the top surface of the substrate 202 but above the bottom boundary of the p-type doping region 226, as shown in FIG. 6A).

As further shown in FIG. 6A, a portion of the substrate 202 over the film 234 is laterally removed. For example, an etch tool may use a wet etch technique, a dry etch technique, a plasma-enhanced etch technique, and/or another type of etch technique to remove the portion of the substrate 202. The etching removes some of the p-type doping region 226 but allows for a film 232 (as described in connection with FIG. 6B) to be formed with a larger width (e.g., as described in connection with FIG. 2D).

As shown in FIG. 6B, the HM 402 may be removed. For example, the HM 402 may be removed as described in connection with FIG. 4D.

As further shown in FIG. 6B, the film 232 may be formed in the recess 404. For example, a deposition tool may form the film 232 over the film 234. In some implementations, a deposition tool forms the film 232 using a spin-coating technique, a CVD technique, a PVD technique, an ALD technique, and/or another deposition technique. The film 232 may overflow the recess 404 such that a planarization tool removes excess material (e.g., using a CMP technique), and a top surface of the film 232 is approximately level (e.g., within 1%, 10%, or a similar margin of error) with a top surface of the substrate 202. The dummy material 406, the film 234, and the film 232 may function as a dummy isolation structure.

As shown in FIG. 6C, a photodiode 104 may be formed in the substrate 202. For example, the photodiode 104 may be implanted as described in connection with FIG. 4E.

As shown FIG. 6D, a p-type well 204 may be formed adjacent to the photodiode 104 and the transfer gate 210 (as well as adjacent to the dummy isolation structure). For example, the p-type well 204 may be formed as described in connection with FIG. 4F.

As shown in FIG. 6E, a recess 408 may be formed in the substrate 202. The recess 408 may be formed as described in connection with FIG. 4G. As further shown in FIG. 6E, a gate dielectric 218 may be formed over and/or on the top surface of the substrate 202. The gate dielectric 218 may be formed as described in connection with FIG. 4G.

As shown in FIG. 6F, the transfer gate 210 may be formed over and/or on the gate dielectric 218 as well as in the recess 408. For example, the transfer gate 210 may be formed as described in connection with FIG. 4H.

As shown in FIG. 6G, a drain extension region 208 may be formed adjacent to (and thus associated with) the transfer gate 210. For example, the drain extension region 208 may be implanted as described in connection with FIG. 4I. As further shown FIG. 6G, an n-type doping region 206 may be formed adjacent to the photodiode 104 and the transfer gate 210 (as well as adjacent to the dummy isolation structure). For example, the n-type doping region 206 may be implanted as described in connection with FIG. 4I. The n-type doping region 206 includes the film 232 in the example implementation 600.

As shown in FIG. 6H, a dielectric layer 212 may be formed over the substrate 202. The dielectric layer 212 may be deposited as described in connection with FIG. 4J. Additionally, as shown in FIG. 6H, a conductive structure 214 may be formed to contact the n-type doping region 206, and a conductive structure 216 may be formed to contact the transfer gate 210). The conductive structures 214 and 216 may connect to a BEOL. For example, the structure shown in FIG. 6H may be bonded to an additional chip including the BEOL (e.g., an ASIC 118, as described in connection with FIG. 1A). In implementations where pixel transistors (e.g., the reset gate 110, the SF transistor 112, and the RS transistor 114) are on a separate chip from the photodiode 104, the chips may be bonded together such that a combined structured is bonded to the additional chip including the BEOL.

As shown in FIG. 6I, the dummy material 406 may be removed and replaced with dielectric materials 222a and 222b. Accordingly, the dielectric materials 222a and 222b may function as an isolation structure with the films 232 and 234.

As indicated above, FIGS. 6A-6I are provided as an example. Other examples may differ from what is described with regard to FIGS. 6A-6I. For example, the recess 404 may be formed using a plurality of layers rather than a single HM layer. The plurality of layers may include a bottom layer, a middle layer, and a photoresist layer. Additionally, or alternatively, a sidewall may be formed on the transfer gate 210 (e.g., after formation of the drain extension region 208).

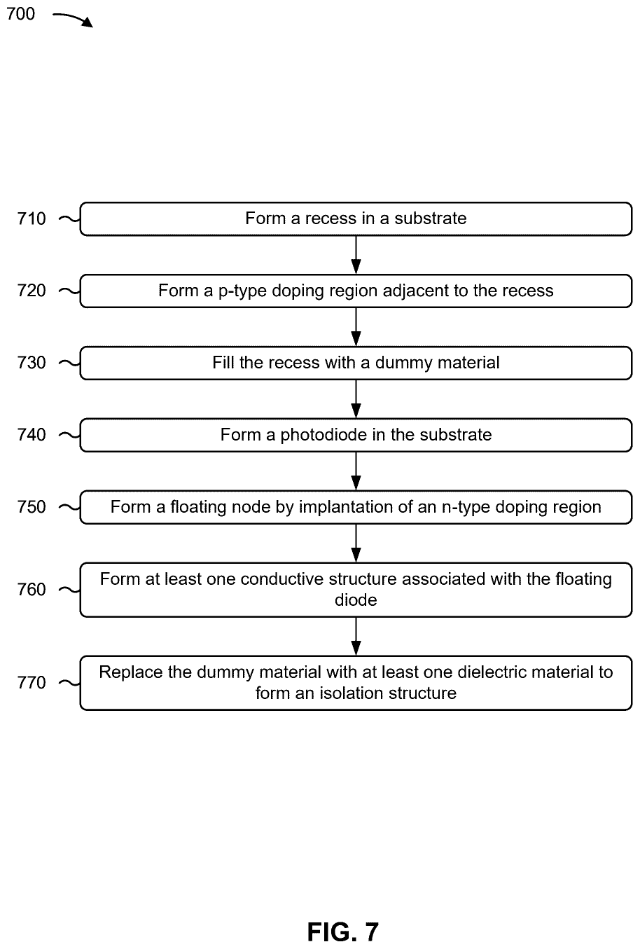

FIG. 7 is a flowchart of an example process 700 associated with forming a pixel sensor described herein. In some implementations, one or more process blocks of FIG. 7 are performed using one or more semiconductor processing tools. Additionally, or alternatively, one or more process blocks of FIG. 7 may be performed using one or more components of a device, such as a processor, a memory, an input component, an output component, and/or a communication component.

As shown in FIG. 7, process 700 may include forming a recess in a substrate (block 710). For example, one or more of the semiconductor processing tools may be used to form a recess 404 in a substrate 202, as described herein.

As further shown in FIG. 7, process 700 may include forming a p-type doping region adjacent to the recess (block 720). For example, one or more of the semiconductor processing tools may be used to form a p-type doping region 226 adjacent to the recess 404, as described herein.

As further shown in FIG. 7, process 700 may include filling the recess with a dummy material (block 730). For example, one or more of the semiconductor processing tools may be used to fill the recess 404 with a dummy material 406, as described herein.

As further shown in FIG. 7, process 700 may include forming a photodiode in the substrate (block 740). For example, one or more of the semiconductor processing tools may be used to form a photodiode 104 in the substrate 202, as described herein.

As further shown in FIG. 7, process 700 may include forming a floating node by implantation of an n-type doping region (block 750). For example, one or more of the semiconductor processing tools may be used to form a floating node 108 by implantation of an n-type doping region 206, as described herein.

As further shown in FIG. 7, process 700 may include forming at least one conductive structure associated with the floating node (block 760). For example, one or more of the semiconductor processing tools may be used to form at least one conductive structure 214/216 associated with the floating node 108, as described herein.

As further shown in FIG. 7, process 700 may include replacing the dummy material with at least one dielectric material to form an isolation structure (block 770). For example, one or more of the semiconductor processing tools may be used to replace the dummy material 406 with at least one dielectric material 222 to form an isolation structure 220, as described herein.

Process 700 may include additional implementations, such as any single implementation or any combination of implementations described below and/or in connection with one or more other processes described elsewhere herein.

In a first implementation, process 700 includes bonding a first chip 102 that includes the photodiode 104, the floating node 108, and the at least one conductive structure 214/216 to a second chip 116 that includes an integrated circuit 118.

In a second implementation, process 700 includes bonding a first chip 102 that includes the photodiode 104 and the floating node 108 to a third chip 152 that includes at least one transistor 110/112/114, and bonding the third chip 152 to a second chip 116 that includes an integrated circuit 118.

In a third implementation, alone or in combination with one or more of the first and second implementations, forming the p-type doping region 226 includes at least one of: performing implantation of the p-type doping region 226, performing plasma doping to form the p-type doping region 226, or performing laser doping to form the p-type doping region 226.

In a fourth implementation, alone or in combination with one or more of the first through third implementations, process 700 includes forming a gate material 218 over the substrate 202, where at least one film 224/232/234 separates the gate material 218 from the at least one dielectric material 222 of the isolation structure 220.

In a fifth implementation, alone or in combination with one or more of the first through fourth implementations, process 700 includes etching a portion of the dummy material 406 and forming at least one film 224/232/234 over the dummy material 406.

In a sixth implementation, alone or in combination with one or more of the first through fifth implementations, forming the photodiode 104 includes performing implantation of the photodiode 104 on a backside of the substrate 202, where the isolation structure 220 is associated with a frontside of the substrate 202.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a p-type doping region around an isolation structure provides additional electrical isolation between pixel sensors of a pixel array. As a result, current leakage from a floating node of one pixel sensor into another is reduced. Therefore, dark current is reduced, and performance of the pixel array is improved. Additionally, pixel noise caused by electrons trapped in the isolation structure may be reduced.

As described in greater detail above, some implementations described herein provide a semiconductor structure. The semiconductor structure includes a photodiode in a substrate and a floating node including an n-type doping region. The semiconductor structure includes an isolation structure surrounding the photodiode. The semiconductor structures includes a p-type doping region, between the n-type doping region of the floating node and the isolation structure, and configured to absorb excess charge from the isolation structure.

As described in greater detail above, some implementations described herein provide a method. The method includes forming a recess in a substrate. The method includes forming a p-type doping region adjacent to the recess. The method includes filling the recess with a dummy material. The method includes forming a photodiode in the substrate. The method includes forming a floating node by implantation of an n-type doping region. The method includes forming at least one conductive structure associated with the floating node. The method includes replacing the dummy material with at least one dielectric material to form an isolation structure.

As described in greater detail above, some implementations described herein provide a semiconductor structure. The semiconductor structure includes a photodiode in a substrate and a transfer gate associated with a drain region. The semiconductor structure includes an isolation structure surrounding the photodiode. The semiconductor structure includes a p-type doping region, between the drain region and the isolation structure, and configured to absorb excess charge from the isolation structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a photodiode in a substrate;
a floating node including an n-type doping region;
an isolation structure surrounding the photodiode; and
a p-type doping region, between the n-type doping region of the floating node and the isolation structure, and configured to absorb excess charge from the isolation structure.

2. The semiconductor structure of claim 1, further comprising:
a transfer gate connected to the floating node.

3. The semiconductor structure of claim 1, wherein the floating node further includes a drain extension region.

4. The semiconductor structure of claim 1, further comprising:
at least one film adjacent to the p-type doping region and over a dielectric material of the isolation structure.

5. The semiconductor structure of claim 4, wherein the at least one film includes a first film and a second film, and the p-type doping region contacts the first film and the second film.

6. The semiconductor structure of claim 4, wherein the at least one film includes a first film and a second film, the first film is wider than the second film, and the p-type doping region contacts the second film.

7. The semiconductor structure of claim 1, further comprising:
a conductive structure that contacts a portion of the substrate adjacent to the isolation structure.

8. The semiconductor structure of claim 1, further comprising:
a conductive structure that contacts a portion of a film over a dielectric material of the isolation structure.

9. A method, comprising:
forming a recess in a substrate;
forming a p-type doping region adjacent to the recess;
filling the recess with a dummy material;
forming a photodiode in the substrate;
forming a floating node by implantation of an n-type doping region;
forming at least one conductive structure associated with the floating node; and
replacing the dummy material with at least one dielectric material to form an isolation structure.

10. The method of claim 9, further comprising:
bonding a first chip that includes the photodiode, the floating node, and the at least one conductive structure to a second chip that includes an integrated circuit.

11. The method of claim 9, further comprising:
bonding a first chip that includes the photodiode and the floating node to a third chip that includes at least one transistor; and
bonding the third chip to a second chip that includes an integrated circuit.

12. The method of claim 9, wherein forming the p-type doping region includes at least one of:
performing implantation of the p-type doping region;
performing plasma doping to form the p-type doping region; or
performing laser doping to form the p-type doping region.

13. The method of claim 9, further comprising:
forming a gate material over the substrate,
wherein at least one film separates the gate material from the at least one dielectric material of the isolation structure.

14. The method of claim 13, further comprising:
etching a portion of the dummy material; and
forming the at least one film over the dummy material.

15. The method of claim 9, wherein forming the photodiode comprises:
performing implantation of the photodiode on a backside of the substrate,
wherein the isolation structure is associated with a frontside of the substrate.

16. A semiconductor structure, comprising:
a photodiode in a substrate;
a transfer gate associated with a drain region;
an isolation structure surrounding the photodiode; and
a p-type doping region, between the drain region and the isolation structure, and configured to absorb excess charge from the isolation structure.

17. The semiconductor structure of claim 16, wherein a ratio of a depth of the p-type doping region to a width of the p-type doping region is in a range from approximately 0.6 to approximately 200.0.

18. The semiconductor structure of claim 16, wherein a concentration associated with the p-type doping region is in a range from approximately 1.0×10¹⁷ inverse cubic centimeters (cm⁻³) to approximately 1.0×10²¹ cm⁻³.

19. The semiconductor structure of claim 16, wherein a ratio of a depth of the isolation structure to a depth of the p-type doping region is in a range from approximately 2.50 to approximately 266.67.

20. The semiconductor structure of claim 16, wherein a ratio of a width of the isolation structure to a width of the p-type doping region is in a range from approximately 1.0 to approximately 60.0.
